(19) United States
(12) Patent Application Publication
(10) Pub. No.: US 2025/0372448 A1
(43) Pub. Date: Dec. 4, 2025

(54) METHODS FOR FORMING LOW RESISTIVITY CONTACTS

(71) Applicant: Applied Materials, Inc., Santa Clara, CA (US)

(72) Inventors: Yiyang WAN, Sunnyvale, CA (US); Le ZHANG, Santa Clara, CA (US); Chih-Hsun HSU, Santa Clara, CA (US); Weifeng YE, San Jose, CA (US); Shumao ZHANG, San Jose, CA (US); Wei ZHANG, Sunnyvale, CA (US); Qihao ZHU, Sunnyvale, CA (US); Yiyang LU, San Jose, CA (US); Liqi WU, San Jose, CA (US); Jiang LU, Milpitas, CA (US)

(21) Appl. No.: 19/009,638

(22) Filed: Jan. 3, 2025

Related U.S. Application Data
(60) Provisional application No. 63/656,054, filed on Jun. 4, 2024.

(51) Int. Cl. H01L 21/768

(52) U.S. Cl. CPC H01L 21/76865; H01L 21/76849; H01L 21/76889; H01L 21/76895

(57) ABSTRACT

The present disclosure generally provides methods of forming contact structures on semiconductor substrates. The methods include forming a metal silicide layer on a surface of a contact structure by maintaining a first temperature of a substrate and providing a first carrier gas, a first metal-containing precursor, and a first hydrogen-containing precursor to a first deposition chamber. The contact structure includes a feature formed in a surface of the semiconductor substrate. The metal silicide layer is formed over the sidewalls and the silicon containing contact. The metal silicide layer is exposed to a chlorine containing plasma to remove at least a portion of the metal silicide layer formed on the sidewalls. A metal layer is formed on a surface of the silicon containing contact. A portion of the formed metal silicide layer is disposed between the metal layer and the surface of the silicon containing contact.

### CROSS-REFERENCE TO RELATED APPLICATIONS

This application claims priority to U.S. Provisional Patent Application Ser. No. 63/656,054, filed on Jun. 12, 2024, which is herein incorporated by reference in its entirety.

### FIELD

Embodiments disclosed herein generally relate to methods for forming low resistivity contacts for semiconductor device formation.

### BACKGROUND

Integrated circuits have evolved into complex devices that can include billions of transistors, capacitors, and resistors on a single chip. In the course of integrated circuit evolution, functional density (that is, the number of interconnected devices per chip area) has generally increased while geometry size (that is, the smallest component (or line) that can be created using a fabrication process) has decreased.

Microelectronic devices are fabricated on a semiconductor substrate as integrated circuits in which various conductive layers are interconnected with one another to permit electronic signals to propagate within the device. Examples of such devices include memory (for example, DRAM (dynamic random access memory)) and logic devices, including both planar and three-dimensional structures. Three-dimensional structures include finFET (fin field-effect transistor) or MOSFET (metal-oxide-semiconductor field-effect transistor) devices.

An example of a finFET or MOSFET device includes a gate electrode on a gate dielectric layer on a surface of a semiconductor substrate. Source/drain regions are provided along opposite sides of the gate electrode. The source and drain regions are generally heavily doped regions of the semiconductor substrate. Usually a silicide layer, for example a titanium silicide layer, is required to form a reliable contact at the formed source and drain regions.

In a traditional contact junction formation process, a feature also referred to as a cavity, a via, or a trench, is fabricated in the semiconductor substrate. In one example, middle-of-the-line (MOL) contact junctions allow connections between front-end-of-the-line (FEOL) semiconductor structures and back-end-of-the-line (BEOL) interconnects. Contacts with a low resistivity are desirable in semiconductor devices. However, when MOL contacts have high resistance, the contacts produce poor connections between the FEOL structures and the BEOL packaging interconnects, reducing the performance of the packaged semiconductor structures.

In traditional contact formation processes, a conformal titanium silicide (TiSi) layer is formed on a silicon or silicon germanium connection as a capping layer and then nitrided to form titanium silicon nitride (TiSiN) to prevent oxidation of the TiSi. The final silicide capping layer is a bilayer of TiSi and TiSiN that is formed over the field, sidewalls and contact regions formed on the substrate. The inventors have observed, however, that the TiSiN layer has a high resistivity (approximately 300 μohms-cm for a thickness of approximately 6 nm). The TiSi(N)/W on the field and sidewall then need to be removed by a wet pull-back process, where physical vapor deposition (PVD) tungsten (W) only remains at the bottom of the via. Due to PVD technology limitations, it is challenging to deposit a continuous PVD W film at the high sloped area of the capping layer. Once the pull-back process has been completed, a selective metal deposition process (e.g., tungsten or molybdenum deposition process) can either partially or fully fill up the via. For example, a feature is filled with a low resistivity metal, either by cobalt (Co), molybdenum (Mo), or tungsten (W). Such an integration flow not only has high resistivity due to the TiSi/TiSiN bilayer, but also high cost due to the expensive thick FFW ALD deposition process and the pull-back process for thick TiN/PVD W.

Therefore, there is a need for improved methods to reduce contact resistance and simplified processes of forming low resistance contacts.

### SUMMARY

In an embodiment, the present disclosure generally provides methods of forming contact structures on semiconductor substrates. The methods include forming a metal silicide layer on a surface of a contact structure by maintaining a first temperature of a first substrate and providing a first carrier gas, a first metal-containing precursor, and a first hydrogen-containing precursor to a first deposition chamber. The contact structure includes a feature formed in a surface of the semiconductor substrate. The feature includes an opening that is defined by a silicon containing contact and sidewalls. The feature includes a dielectric material. The metal silicide layer is formed over the sidewalls and the silicon containing contact. The metal silicide layer formed over the sidewalls and the silicon containing contact are exposed to a nitrogen or ammonia containing plasma to cause a portion of the metal silicide layer to form a nitride metal silicide layer. The nitride metal silicide layer is exposed to a chlorine (Cl₂) containing plasma to remove the portion of the nitride metal silicide layer from the sidewalls and the silicon containing contact. A metal layer is formed on a surface of the silicon containing contact. A portion of the formed metal silicide layer is disposed between the metal layer and the surface of the silicon containing contact.

In another embodiment, the present disclosure generally provides methods of forming contact structures on semiconductor substrates. The methods include forming a metal silicide layer on a surface of a contact structure by maintaining a first temperature of a substrate and providing a first carrier gas, a first metal-containing precursor, and a first hydrogen-containing precursor to a first deposition chamber. The contact structure includes a feature formed in a surface of the semiconductor substrate. The feature includes an opening that is defined by a silicon containing contact and sidewalls. The feature includes a dielectric material. The metal silicide layer is formed over the sidewalls and the silicon containing contact. The metal silicide layer is exposed to a chlorine (Cl₂) containing plasma to remove at least a portion of the metal silicide layer formed on the sidewalls. A metal layer is formed on a surface of the silicon containing contact. A portion of the formed metal silicide layer is disposed between the metal layer and the surface of the silicon containing contact.

In another embodiment, the present disclosure generally provides methods of forming contact structures on semiconductor substrates. The methods include forming a metal silicide layer on a surface of a contact structure by maintaining a first temperature of a substrate and providing a first carrier gas, a first metal-containing precursor, and a first hydrogen-containing precursor to a first deposition chamber. The contact structure includes a feature formed in a surface of the semiconductor substrate. The feature includes an opening that is defined by a silicon containing contact and sidewalls. The feature includes a dielectric material. The metal silicide layer is formed over the sidewalls and the silicon containing contact. The metal silicide layer is exposed to a metal chloride containing plasma to remove at least a portion of the metal silicide layer formed on the sidewalls. A metal layer is formed on a surface of the silicon containing contact. A portion of the formed metal silicide layer is disposed between the metal layer and the surface of the silicon containing contact.

In another embodiment, the present disclosure generally provides methods of forming contact structures on semiconductor substrates. The methods include forming a metal silicide layer on a surface of a contact structure by maintaining a first temperature of a substrate and providing a first carrier gas, a first metal-containing precursor, and a first hydrogen-containing precursor to a first deposition chamber. The contact structure includes a feature formed in a surface of the semiconductor substrate. The feature includes an opening that is defined by a silicon containing contact and sidewalls. The feature includes a dielectric material. The metal silicide layer is formed over the sidewalls and the silicon containing contact. The metal silicide layer formed over the sidewalls and the silicon containing contact is exposed to an oxygen containing plasma to cause a portion of the metal silicide layer to form an oxidized metal silicide layer. The oxidized metal silicide layer is exposed to an oxide removal proves. The oxide removal process includes exposing the oxidized metal silicide layer to a metal chloride containing precursor to remove at least a portion of the oxidized metal silicide layer formed on the sidewalls. The substrate is exposed to a plasma or thermal based fluorine etching process. A metal layer is formed on a surface of the silicon containing contact. A portion of the formed metal silicide layer is disposed between the metal layer and the surface of the silicon containing contact.

### BRIEF DESCRIPTION OF THE DRAWINGS

Embodiments of the present principles, briefly summarized above and discussed in greater detail below, can be understood by reference to the illustrative embodiments of the principles depicted in the appended drawings found in the Appendix. However, the appended drawings illustrate only typical embodiments of the principles and are thus not to be considered limiting of scope, for the principles may admit to other equally effective embodiments.

FIG. 1A (Prior Art) is a cross-section view of a portion of a semiconductor structure, according to embodiments of the present disclosure.

FIG. 1B is a cross-section view of a portion of a semiconductor structure, according to embodiments of the present disclosure.

FIG. 1C is a cross-section view of a portion of a semiconductor structure, according to embodiments of the present disclosure.

FIG. 2 is a flow chart of a method of selective chemical vapor deposition (CVD) TiSi deposition and TiSi/W integration, according to embodiments of the present disclosure.

FIGS. 3A, 3B, 3C, 3D, and 3E are cross-sectional views of a portion of a semiconductor substrate based on the method of FIG. 2, according to embodiments of the present disclosure.

FIG. 4 is a flow chart of a method of selective CVD TiSi deposition and TiSi/W integration, according to embodiments of the present disclosure.

FIGS. 5A, 5B, 5C, 5D, 5E, and 5F are cross-sectional views of a portion of a semiconductor substrate based on the method of FIG. 4, according to embodiments of the present disclosure.

FIG. 6 is a flow chart of a method of selective TiSi and TiN deposition, according to embodiments of the present disclosure.

FIGS. 7A, 7B, 7C, 7D, 7E, 7F, 7G, and 7H are cross-sectional views of a portion of a semiconductor substrate based on the method of FIG. 6, according to embodiments of the present disclosure.

FIG. 8 is a flow chart of a method of selective TiSi and TiN deposition, according to embodiments of the present disclosure.

FIGS. 9A, 9B, 9C, 9D, 9E, and 9F are cross-sectional views of a portion of a semiconductor substrate based on the method of FIG. 8, according to embodiments of the present disclosure.

FIG. 10 is a flow chart of a method of an etching process, according to embodiments of the present disclosure.

FIGS. 11A, 11B, 11C, 11D, 11E, and 11F are cross-sectional views of a portion of a semiconductor substrate based on the method of FIG. 10, according to embodiments of the present disclosure.

FIG. 12 is a diagrammatic view of an integrated tool, according to embodiments of the present disclosure.

FIG. 13 illustrates a graphical representation of an etch amount of SiN/Si, according to embodiments of the present disclosure.

FIG. 14 illustrates a graphical representation of an etch amount of SiN/Si, according to embodiments of the present disclosure.

FIG. 15 illustrates a graphical representation of an etch amount of SiN/Si, according to embodiments of the present disclosure.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

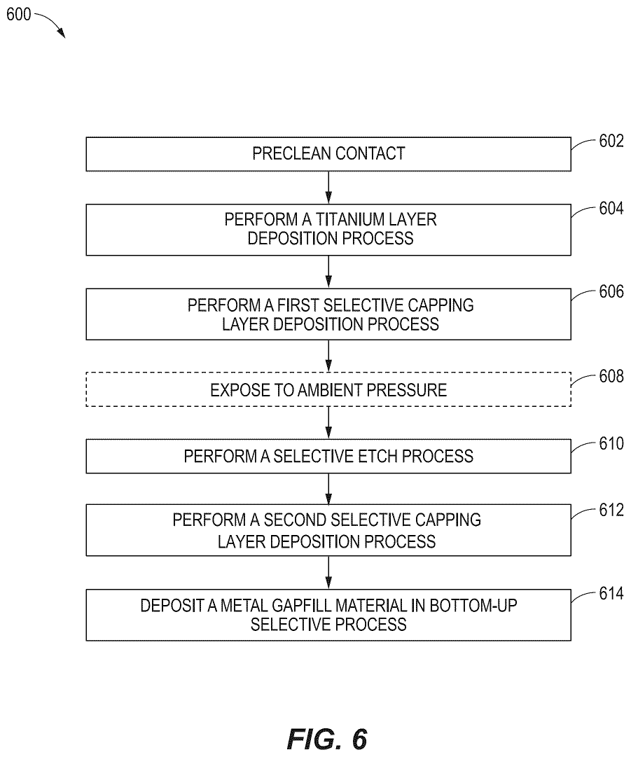

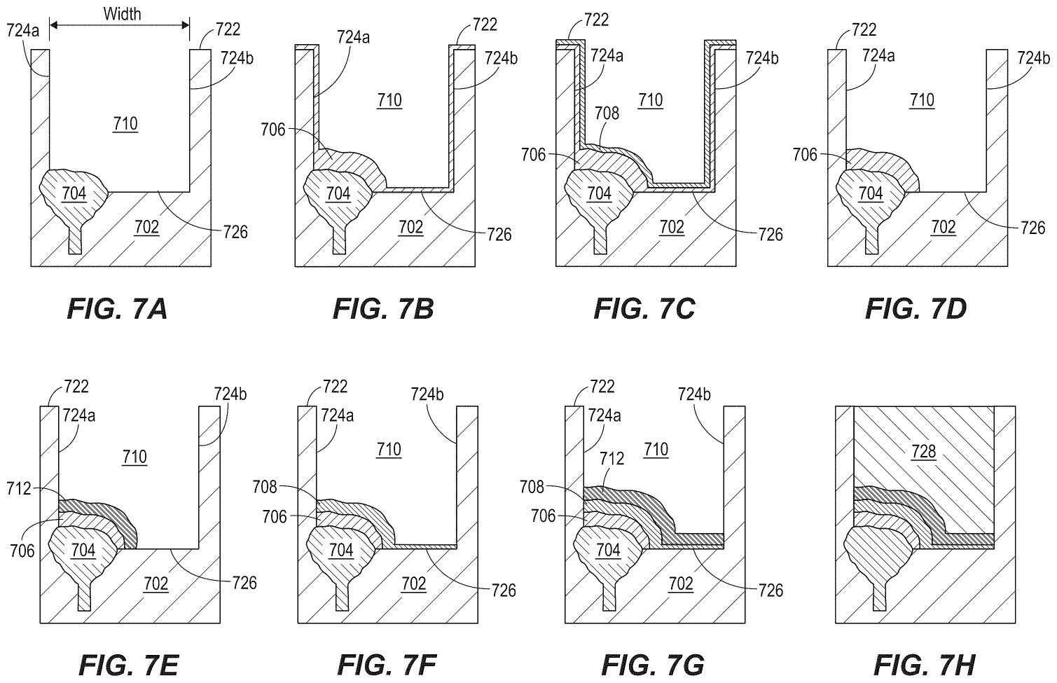

Methods of the present disclosure provide middle-of-the-line (MOL) contacts with reduced resistivity. Methods can integrate multiple MOL processes on the same integrated tool as well as achieve low contact resistance (Rc). For example, a process has been developed that selectively etches a capping layer by use of a selective etching process such that the selectivity towards the capping layer is maintained, thereby reducing resistivity by removing the capping layer prior to deposition of a tungsten (W) cap and/or liner. As a further example, as further discussed in relation to FIGS. 6 and 7A-7E, a process has been developed that selectively etches a titanium silicon nitride layer by use of a selective etching process such that the deposition of a low resistance gap fill material is selective towards a bottom surface of the cavity, via, and/or trench, thereby reducing resistivity by preventing seam formation within the gap fill material.

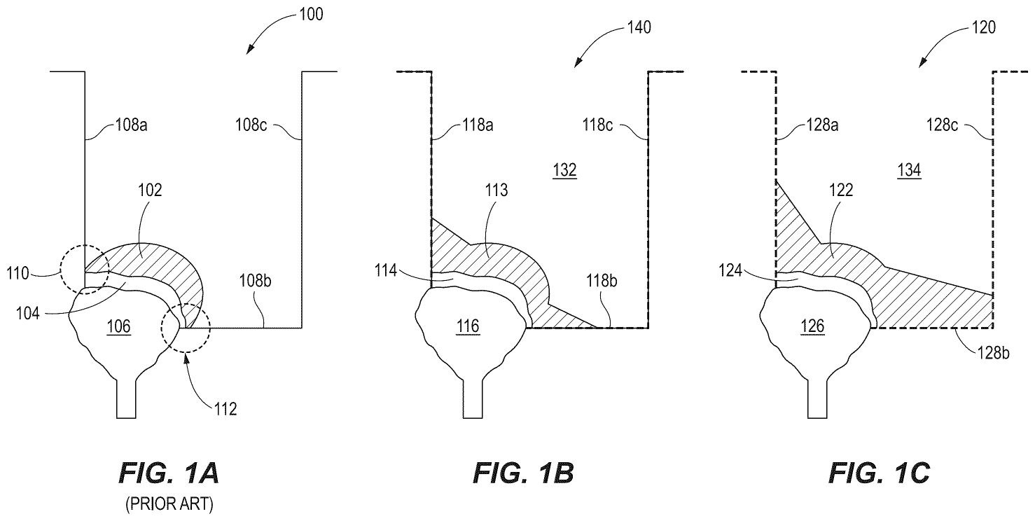

FIGS. 1A, 1B, and 1C are each a schematic illustration of a structure having a tungsten layer disposed on a capping layer. As shown in FIG. 1A (Prior Art), structure 100 has a metal layer 102, e.g., tungsten and/or molybdenum, which has been selectively deposited on a capping layer 104, e.g., a TiSi capping layer. Capping layer 104 is disposed on contact structure 106. For conventional selective deposition processes like that shown in FIG. 1A, metal deposition selectivity is high on the capping layer, e.g., TiSi, instead of dielectric surfaces 108a, 108b, and 108c. However, the metal layer 102 is thinner at the periphery of the capping layer 104 at location 110 and location 112 where the capping layer 104 joins the sidewall of dielectric surface 108a and dielectric surface 108b, respectively. However, at locations 110 and 112, the capping layer and surrounding dielectric material at such locations is more prone to be damaged by exposure to oxygen from a subsequent vacuum break (e.g., exposure to atmosphere) or damaged due to exposure to fluorine during a subsequent W or Mo deposition process.

In contrast, deposition processes of the present disclosure can provide a selective capping profile where the capping layer is restricted to just the contact structures such that the metal layer is deposited onto adjacent dielectric surfaces. For example, as shown in FIG. 1B, structure 140 has a metal layer 113 which has been partially selectively disposed on a capping layer 114 and over a portion of the dielectric surfaces 118a and 118b within the cavity 132. Capping layer 114 is disposed on contact structure 116. Without being bound by theory, the metal deposition selectivity, e.g., tungsten deposition selectivity and/or molybdenum deposition selectivity, is high on the capping layer surface instead of the other exposed dielectric surfaces that are not in contact with the capping layer, such as the dielectric surface 118c, the upper portion of the dielectric surface 118a or field region outside of the feature. However, as shown in FIG. 1B, the metal deposition selectivity towards the capping layer 104 is reduced at the dielectric surface 118a and the dielectric surface 118b, as compared to selectivity toward capping layer 104 versus dielectric surface 108a and dielectric surface 108b of structure 100 of FIG. 1A.

As shown in FIG. 1C, structure 120 has a metal layer 122 which has been deposited on the capping layer 124 within the cavity 134. Capping layer 124 is disposed on contact structure 126. For partially selective deposition like that shown in FIG. 1C, metal deposition selectivity is high on the capping layer. In addition, as shown in FIG. 1C, metal deposition selectivity is provided at dielectric surface 128a, dielectric surface 128b, and dielectric surface 128c, with at least some selectivity being preferential at dielectric surface 128b as compared to each of the exposed dielectric surface 128a and dielectric surface 128c, and selectivity being preferential at dielectric surface 128a as compared to dielectric surface 128c. By use of the processes described herein, the deposited metal layer is able to form over regions of the dielectric surface, and thus is not constrained to form on the capping layer. For example, the partial selectivity deposition process can form products formed by metal (e.g., tungsten) deposition onto a capping layer and such products also tend to deposit onto adjacent dielectric surfaces that are in proximity to the metal (e.g., tungsten) deposition also occurring. Partially selective metal deposition processes of the present disclosure can be tunable (e.g., pressure, dosing, etc.) in order to promote such partially selective metal deposition onto the capping surface and adjacent dielectric surfaces.

### Contact Formation Process Examples

Processes of the present disclosure can provide selective pull back processes of the capping layers, e.g., TiSiN capping layers, to eliminate and/or reduce nitrided and/or oxidized capping layers that degrade device performance due to high resistivity. The methods of the present disclosure also leverage a highly selective chemical vapor deposition (CVD) TiSi deposition process along with an in-situ TiSi/W integration flow.

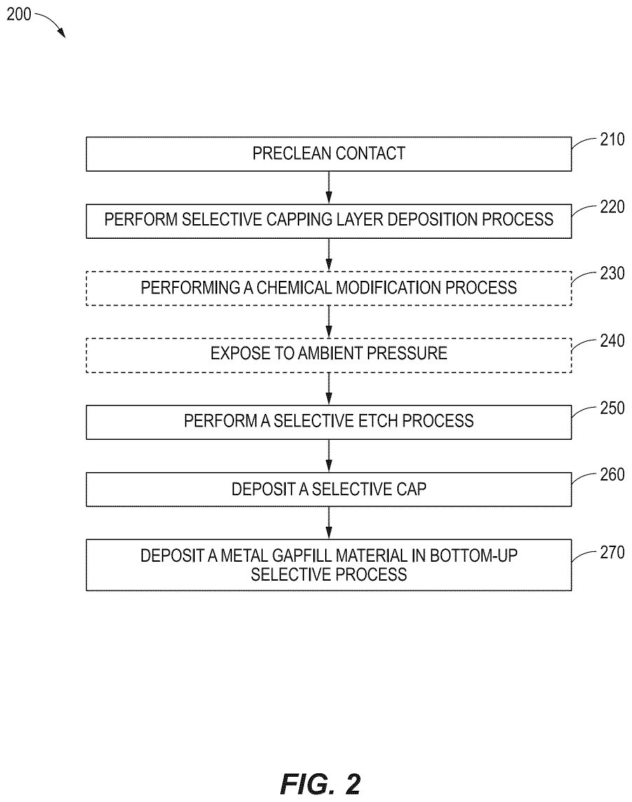

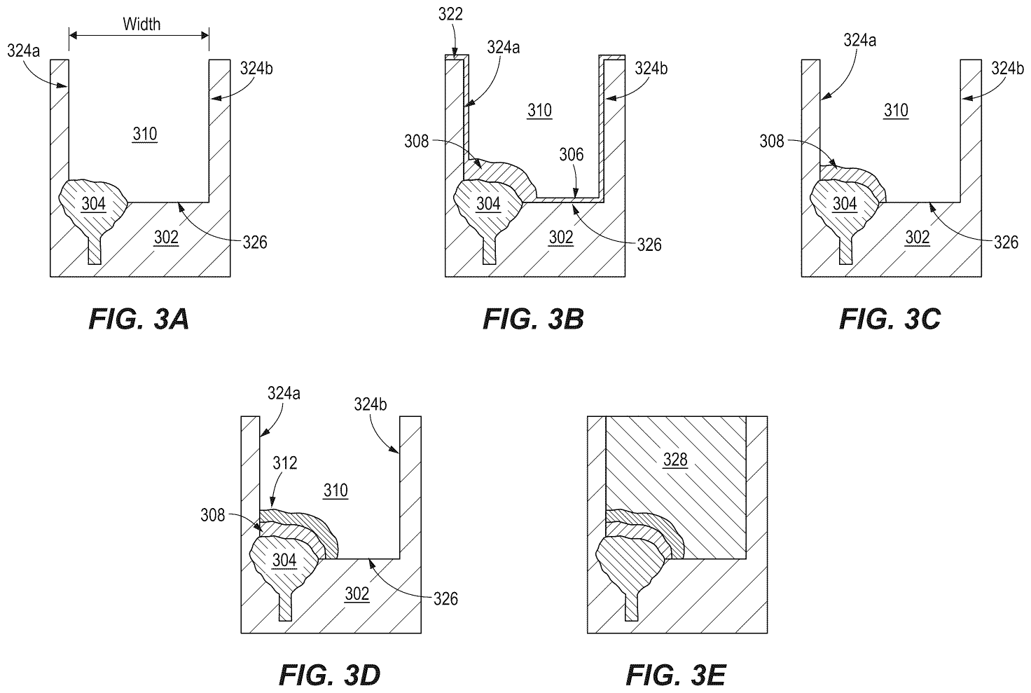

The methods of the present disclosure can be effective for metal gapfill processes in general and may be used with other metal gapfill material besides tungsten such as, for example, molybdenum and the like. For the sake of brevity, examples discussed use tungsten but are not meant to be limited to only tungsten. In the method 200 of FIG. 2, a selective CVD TiSi deposition and TiSi/W integration flow is shown. In the discussion of the method 200, references will be made to FIGS. 3A-3E. At operation 210, a preclean process is performed to remove any contaminates and/or oxidation from surfaces of a contact structure as depicted in FIG. 3A. The contact structure has a silicon-based portion 304 that is exposed in a cavity 310 of a substrate 302 formed of a dielectric material (e.g., silicon dioxide, silicon nitride, etc.). In some embodiments, the silicon-based portion 304 may be a silicon material or a silicon germanium (SiGe) material.

In one or more embodiments, cavities (e.g., vias) can have an average width. For example, cavity 310 can have a width (shown in FIG. 3A) of about 35 nanometers (nm) or less, such as about 5 nm to about 35 nm, such as about 5 nm, 10 nm, and 15 nm to about 20 nm, 25 nm, 30 nm, or 35 nm. In one or more embodiments, cavity 310 can have an aspect ratio (depth:width) of about 1:1 to about 100:1, such as about 10:1, 15:1, or 25:1 to about 35:1, 45:1, or 50:1. At operation 220, a selective deposition process is performed to produce a titanium containing layer 308 on the silicon-based portion 304 as depicted in FIG. 3B. For example, the titanium containing layer can include a Ti layer, a TiN layer, and/or a TiSi layer. TiSi is TiₓSi_{y} which may include Ti₅Si₃, TiSi₂, TiSi, or combinations thereof. The process is selective to the silicon-based portion 304 over the dielectric material of the substrate 302, but a thin titanium containing layer 308 may also form on the surfaces of the field region 322 of the substrate 302 and on sidewalls 324a, 324b in the cavity 310, including a bottom surface 326 of the cavity 310. In some embodiments, the selective deposition process is a CVD TiSi process, e.g., a plasma enhanced CVD process (PECVD), with selectivity on silicon (Si) or silicon germanium (SiGe) over oxide/SiN of approximately greater than 30:1 (vol/vol). The selective deposition process can provide a thickness of TiSi of approximately 3 nm to approximately 9 nm on the silicon-based portion 304, in which a selectivity loss on the field region 322 or sidewalls 324a, 324b and the bottom surface 326 of the cavity 310 is generally less than approximately 1 angstrom to approximately 30 angstroms.

Selective TiSi deposition can be performed using any suitable CVD or atomic layer deposition (ALD) process. In some embodiments, the CVD or ALD process includes utilizing a plasma with a carrier gas. The plasma/carrier gas may then be introduced towards the surface of the semiconductor substrate. In one or more embodiments, the carrier gas includes a noble gas, such as argon, neon, helium, or combinations thereof.

In one or more embodiments, selective deposition is performed by introducing a hydrogen-containing precursor by utilizing a conductively coupled plasma (CCP) deposition. In one or more embodiments, selective deposition includes introducing a hydrogen-containing precursor and a metal-containing precursor with the carrier gas. In one or more embodiments, the metal-containing precursor gas may be fluorine free to prevent formation of metal fluoride solids that have undesirable resistivity properties. The hydrogen-containing precursor can include molecular hydrogen (H₂) and the metal-containing precursor is titanium chloride (TiCl₄). Without being bound by theory, the introduction of both the hydrogen-containing and the metal-containing precursors into the carrier gas causes both precursors to become energized on a molecular level to a point of at least partial disassociation in the carrier gas. For example, titanium chloride may disassociate into titanium-based ions (Ti⁺, TiClₓ⁺) or free radial titanium trichloride (TiCl₃⁺); hydrogen may disassociate into hydronium ions (H⁺) or hydrogen free radicals (H*). The dissociated species may then interact with the silicon surface of the silicon-containing contact, donate electrons to the silicon atoms and then each species interact with one another and form the titanium silicide layer on the top of the silicon-based portion 304.

In one or more embodiments, the selective deposition is performed by maintaining the semiconductor substrate at a first metal deposition temperature. In one or more embodiments, the semiconductor substrate is maintained at a metal deposition temperature of about 200° C. to 800° C., such as about 200° C., 300° C., 400° C., 450° C., and 500° C. to about 600° C., 700° C., and 800° C., for a period of about 5 seconds to about 20 seconds, in which an inert gas may be present. The inert gas flowing over the semiconductor substrate may facilitate in cooling and affixing the deposition material (e.g., TiSi) on the top of the silicon-containing contact as well as removing volatilized products and unreacted materials, such as molecular hydrogen and hydrogen chloride (HCl).

At operation 230, optionally, a chemical modification process is performed on the titanium containing layer 308 to produce a TiSiN layer 306, as shown in FIG. 3B. The chemical modification process can include a nitridation process via flowing a nitrogen based gas such as ammonia, a nitrogen radical such as an ammonia radical, and/or a nitrogen based compound such as ammonia over the titanium containing layer 308 to convert the titanium containing layer 308 into a TiSiN layer 306. The chemical modification process can include flowing 500 sccm to about 6000 sccm of nitrogen gas, e.g., ammonia, over the titanium containing layer 308. At operation 240, optionally, the TiSiN layer 306 is exposed to ambient pressure, e.g., performing a vacuum break. Without being bound by theory, the TiSiN layer 306 may protect the titanium containing layer 308 from oxidizing.

At operation 250, a selective etch process is performed to remove the titanium containing layer 308 or the TiSiN layer, thereby exposing and/or etching the titanium containing layer 308, e.g., an etch back process, as shown in FIG. 3C. For example, the titanium containing layer 308 can be selectively etched to expose and/or etch a top surface of the titanium containing layer 308. The selective etch process selectively targets the TiSiN layer 306. The selective etch process includes flowing an etching gas and optional inert gas into the processing region. The etching gas can include chlorine or fluorine containing gas, or a combination thereof, wherein the etchant is selected to be reactive to the titanium containing layer 308 or the TiSiN layer, over the non-oxide metal, e.g., the substrate 302. In some embodiments, the etching gas may include WF₆, WOCl₄, WO₂Cl₂, WCl₅, WCl₆, BCl₃, Cl₂, TiCl₄, SiCl₄ or other suitable compound. In some embodiments, the selective etch process is performed at a pressure in a range from about 1 mTorr to about 200 mTorr, at an inductively coupled plasma (ICP) power in a range from about 50 Watts to about 1000 Watts, at a flow rate of argon gas into the processing region in a range from about 50 sccm to about 500 sccm, at a flow rate of Cl₂ gas into the processing region in a range from about 5 sccm to about 250 sccm, at a temperature in a range from about 0 degrees Celsius to about 250 degrees Celsius, and for a time period from about 6 seconds to about 60 seconds.

The selective etch process exposes the titanium containing layer 308 and/or TiSiN layer 306 to an etchant process to selectively remove the titanium containing layer 308 and/or TiSiN layer 306 with minimal removal of the underlying titanium containing layer 308. The selective etch process may be a cyclic process. The selective etch process may be repeated for a number of cycles sufficient to reduce the thickness of the titanium containing layer 308 and/or the TiSiN layer 306 from the initial thickness to a targeted reduced thickness and/or elimination. For example, the selective etch process may be repeated for two to four cycles, for example, two cycles. The selective etch process of operation 250 may be repeated until the titanium containing layer 308 and/or the TiSiN layer are reduced and/or eliminated. In some embodiments, the titanium containing layer 308 and/or the TiSiN layer 306 may remain along the bottom surface 326.

The thickness of the titanium containing layer and/or the TiSiN layer formed over the field region is reduced at a greater rate than a thickness of the titanium containing layer and/or the TiSiN layers formed over the sidewall surfaces and the bottom surfaces of the cavity 310. Additionally, the thickness of the titanium containing layer and/or the TiSiN layer formed over the sidewalls 324a and 324b are reduced at a greater rate than a thickness of the titanium containing layer and/or the TiSiN layer formed over the bottom surface 326.

At operation 260, a metal cap 312 is deposited on the titanium containing layer 308 on the silicon-based portion 304, as shown in FIG. 3D. In some embodiments, the metal cap 312 has an average thickness of about 2.5 nm to about 11 nm, such as about 6 nm to about 9 nm, such as about 8 nm. The metal cap 312 can be deposited by any suitable deposition process, such as CVD or ALD. The metal cap 312 may be deposited using a partially selective deposition process that is a fluorine free metal deposition process of the metal material used for forming the metal cap 312. In some embodiments, the metal cap 312 may be formed of tungsten. In some embodiments, the metal cap 312 may be formed of molybdenum.

The metal cap 312 can include cobalt (Co), molybdenum (Mo), tungsten (W), tantalum (Ta), titanium (Ti), ruthenium (Ru), rhodium (Rh), copper (Cu), iron (Fe), manganese (Mn), vanadium (V), niobium (Nb), hafnium (Hf), zirconium (Zr), yttrium (Y), aluminum (AI), tin (Sn), chromium (Cr), lanthanum (La), iridium (Ir), or combinations thereof. In some embodiments, the metal cap 312 may be formed of tungsten. In some embodiments, the metal cap 312 may be formed of molybdenum. In some embodiments, for example, a metal cap provides metal seeding on a bottom of the cavity 310 (e.g., SiO₂ or SiN surface).

As part of a process of depositing the metal cap 312 onto the titanium containing layer 308 during operation 260, both a metal-containing precursor and a reducing agent are introduced in the process chamber with a carrier gas to form a gas mixture. The gas mixture is then introduced towards the surface of the substrate 302. The carrier gas may include a noble gas, such as argon, neon, and helium, and combinations thereof.

As part of a process of depositing the metal cap 312 onto the titanium containing layer 308, the substrate 302 may be maintained at a metal deposition temperature. In one or more embodiments, the substrate 302 is maintained at a metal deposition temperature of about 300° C. to 550° C., such as from about 300° C., 325° C., 350° C., 375° C., 400° C., 425° C., 450° C., 475° C., to about 475° C., about 500° C., about 525° C. or 550° C., such as about 450° C. to about 470° C. In one or more embodiments, a chamber pressure at which the partially selective metal deposition process is performed is about 50 Torr to about 150 Torr, such as about 80 Torr to about 120 Torr, such as about 80 Torr to about 100 Torr, alternatively about 100 Torr to about 120 Torr. In one or more embodiments, the period of time at which the metal deposition process is performed is about 5 seconds to about 45 seconds, such as about 30 seconds or less, such as about 10 seconds to about 25 seconds. In one or more embodiments, both the TiSi deposition process and the metal deposition process occur in the same process chamber or in different process chambers.

The metal cap 312 may utilize a metal-containing precursor, such as a fluorine free second metal-containing precursor. In one or more embodiments, the introduced metal-containing precursor includes a fluorine-free metal halide. For example, the metal-containing precursor may include a fluorine-free tungsten precursor (FFW). Examples of FFW halides can include tungsten pentachloride (WCl₅), tungsten hexachloride (WCl₆), or combinations thereof. In one or more embodiments, the fluorine-free tungsten precursor includes a tungsten oxyhalide precursor. Examples of a tungsten oxyhalide can include tungsten oxytetrachloride (WOCl₄), tungsten dichloride dioxide (WO₂Cl₂), or combinations thereof. In one or more embodiments, the fluorine-free tungsten precursor is also a chlorine-free tungsten precursor (CFW). Examples of a fluorine-free and chloride-free tungsten precursor can include tungsten pentabromide (WBr₅), tungsten hexabromide (WBr₆), or combinations thereof. In one or more embodiments, the metal-containing precursor includes a fluorine-free metal organic, such as tris(3-hexyne) tungsten carbonyl (W(CO)(CH₃CH₂C≡CCH₂CH₃)₃).

As part of the process of depositing a metal cap 312 onto the titanium containing layer 308 at operation 260, a reducing agent that is reactive with a metal-containing precursor is introduced into the carrier gas along with the metal-containing precursor. The reducing agent may be a hydrogen-containing composition, such as molecular hydrogen (H₂). The reducing agent acts as a proton donor to cause the metal-containing precursor to form a metallic film comprising the metal on top of the TiSi layer.

Operation 260 may include maintaining a flow rate of the metal-containing precursor to a flow rate of the reducing agent into the carrier gas until a metal cap 312 forms on the titanium containing layer 308. In one or more embodiments, reducing agent (e.g., H₂) is provided to the chamber at a flow rate of about 10 slm or greater, such as about 10 slm to about 100 slm, such as about 15 slm to about 50 slm. In one or more embodiments, the metal-containing precursor is provided to the chamber at an ampoule temperature of about 60° C. or greater and a flow rate of about 0.5 slm to about 2 slm, such as about 0.8 slm to about 1.2 slm. In one or more embodiments, the metal-containing precursor and the reducing agent are introduced (into the carrier gas) at a molar ratio of about 10:1 to 1:100, such as about 10:1, 5:1, 2:1, and 1:1 to about 1:2, 1:5, 1:10, 1:20, 1:50, and 1:100. In one or more embodiments, the combined flow rates of metal-containing precursor and reducing agent are in a range of from about 1 vol. % to 70 vol. % of the overall gas mixture, where the remainder of the gas mixture includes the carrier gas.

At high-pressure, high flow conditions, the deposition rate of the metal cap is high over the titanium containing layer 308. Such conditions can cause selectivity loss at the sidewalls 324a, 324b, and the bottom surface 326. Without being bound by theory, the mechanism of selectivity loss is believed to provide higher concentration of reaction byproduct formed at the TiSi interface. Under high pressure where diffusion is limited, such byproduct will not be easily removed from the cavity 310 but will adsorb to sidewalls of the cavity in a bottom to top direction. These adsorbed metal byproducts will act as nucleation centers for metal cap growth. For example, if deposition time is long enough, selectivity will occur from bottom to top trench creating a V-shape profile of the metal cap 312.

In one or more embodiments, the process of depositing a metal cap 312 onto the titanium containing layer 308, such as operation 260, includes introducing an inert gas to the partially selective metal cap deposited semiconductor substrate. The inert gas evacuates the carrier gas, reactants, and products from the partially selective metal cap deposited semiconductor substrate and process chamber used to form the metal cap deposited semiconductor.

In operation 270, a material 328, e.g., metal gapfill material, is deposited in a bottom-up selective process (e.g., a tungsten hexafluoride (WF₆) based selective process (tungsten over dielectric material of the sidewalls 324a, 324b of the cavity 310, etc.)), as shown in FIG. 3E. In some embodiments, a conformal gapfill may be used instead of a bottom-up fill. In some embodiments, for example, the cavity 310 may be filled by conformal CVD using tungsten or molybdenum and the like. In some embodiments, a conformal molybdenum fill can be performed by using MoO₂Cl₂ or MoOCl₄+H₂ processes or a mixture of MoCl₅ with the aforementioned two precursors.

As stated previously, in addition to tungsten as a TiSi capping layer, molybdenum (Mo) can be used as a capping material as well by selective Mo process. Similarly, the structure fill can be done by selective Mo fill or conformal Mo fill. In some embodiments, Mo and W materials can be interchanged or mixture of Mo and W used.

In FIG. 3E, a resultant conformal metal gap fill material 328 has been conformally deposited into cavity 310. In FIG. 3E, metal gap fill material 328 is shown filling the cavity 310. The metal gap fill material 328 is shown in contact with the partially selective metal cap such that the metal gap fill material 328 is in electrical communication with the contact structure, e.g., silicon-based portion 304. The metal gap fill material 328 is also in contact with at least a portion of the sidewalls 324a, 324b.

Any suitable chemical deposition process, including but not limited to CVD or ALD processes, may be utilized for the metal gap fill material process. The metal gap fill material may be applied such that the material is deposited onto the bottom portion of the device feature and then grown upwards towards the semiconductor field region such that the resultant gap fill material at least approaches the field region (as shown in FIG. 3E) or is at least partially level with the field region (not shown).

In one or more embodiments, the metal gap fill material includes one or more of cobalt (Co), molybdenum (Mo), tungsten (W), tantalum (Ta), titanium (Ti), ruthenium (Ru), rhodium (Rh), copper (Cu), iron (Fe), manganese (Mn), vanadium (V), niobium (Nb), hafnium (Hf), zirconium (Zr), yttrium (Y), aluminum (AI), tin (Sn), chromium (Cr), lanthanum (La), iridium (Ir), or any combination thereof. In one or more embodiments, the metal gap fill material includes tungsten (e.g., deposited using WF₆). In one or more embodiments, the conductor material includes molybdenum.

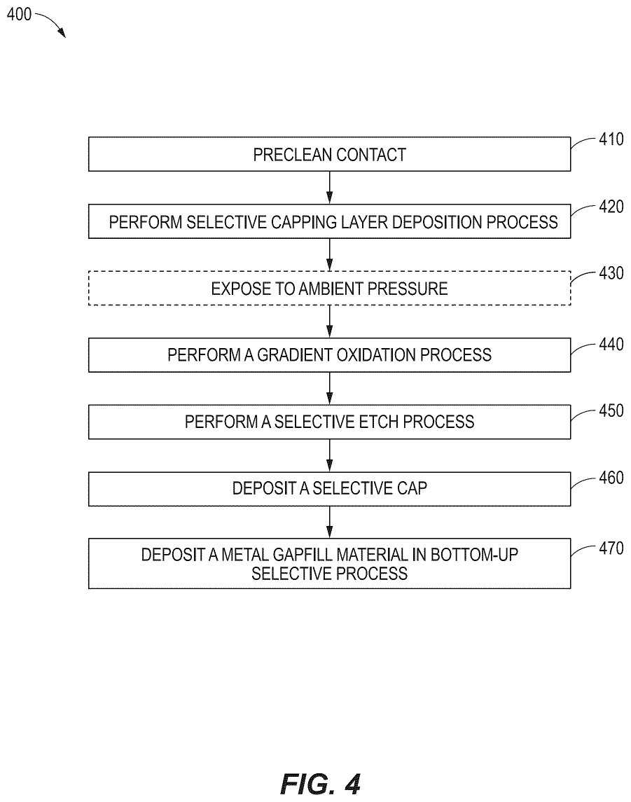

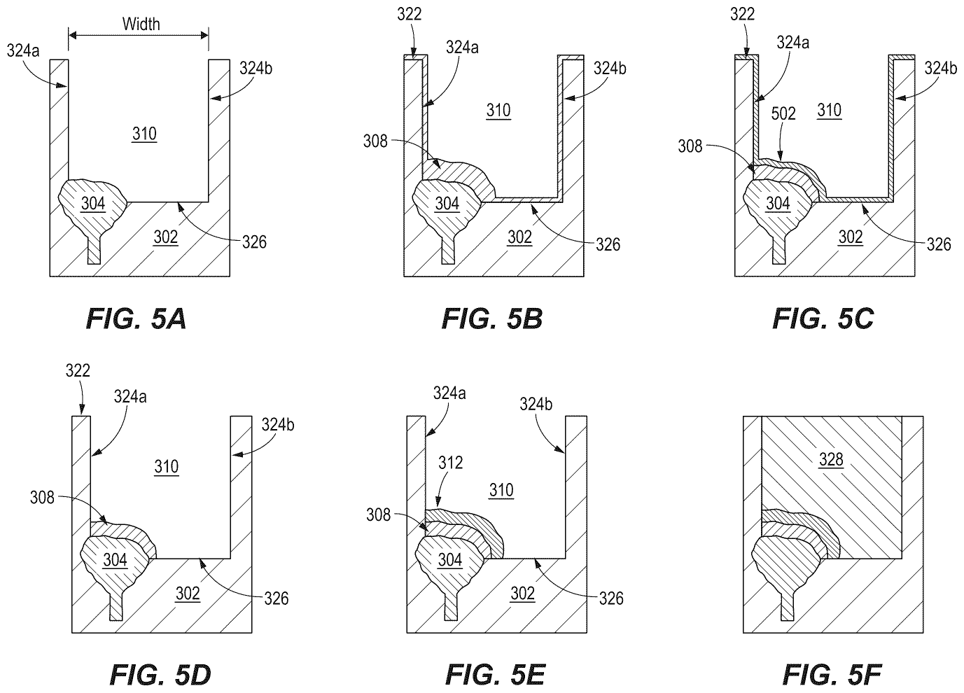

In the method 400 of FIG. 4, a selective CVD TiSi deposition and TiSi/W integration flow is shown. In the discussion of the method 400, references will be made to FIGS. 5A-5F. At operation 410, a preclean process is performed to remove any contaminates and/or oxidation from surfaces of a contact structure as depicted in FIG. 5A. The contact structure has a silicon-based portion 304 that is exposed in a cavity 310 of a substrate 302 formed of a dielectric material (e.g., silicon dioxide, silicon nitride, etc.). In some embodiments, the silicon-based portion 304 may be a silicon material or a silicon germanium (SiGe) material.

In one or more embodiments, cavities (e.g., vias) can have an average width. For example, cavity 310 can have a width (shown in FIG. 5A) of about 35 nanometers (nm) or less, such as about 5 nm to about 35 nm, such as about 5 nm, 10 nm, and 15 nm to about 20 nm, 25 nm, 30 nm, or 35 nm. In one or more embodiments, cavity 310 can have an aspect ratio (depth:width) of about 1:1 to about 100:1, such as about 10:1, 15:1, or 25:1 to about 35:1, 45:1, or 50:1.

At operation 420, a selective deposition process is performed to produce a titanium containing layer 308 on the silicon-based portion 304 as depicted in FIG. 5B. For example, the titanium containing layer can include a Ti layer, a TiN layer, and/or a TiSi layer. TiSi is TiₓSi_{y} which may include Ti₅Si₃, TiSi₂, TiSi, or combinations thereof. The process is selective to the silicon-based portion 304 over the dielectric material of the substrate 302, but a thin titanium containing layer may also form on the surfaces of the field region 322 of the substrate 302 and on sidewalls 324a, 324b in the cavity 310, including a bottom surface 326 of the cavity 310. In some embodiments, the selective deposition process is a CVD TiSi process, e.g., a plasma enhanced CVD process (PECVD), with selectivity on silicon (Si) or silicon germanium (SiGe) over oxide/SiN of approximately greater than 30:1 (vol/vol). The selective deposition process can provide a thickness of TiSi of approximately 3 nm to approximately 9 nm on the silicon-based portion 304, in which a selectivity loss on the field region 322 or sidewalls 324a, 324b and the bottom surface 326 of the cavity 310 is generally less than approximately 1 angstrom to approximately 30 angstroms.

Selective TiSi deposition can be performed using any suitable CVD or ALD process. In some embodiments, the CVD or ALD process includes utilizing a plasma with a carrier gas. The plasma/carrier gas may then be introduced towards the surface of the semiconductor substrate. In one or more embodiments, the carrier gas includes a noble gas, such as argon, neon, helium, or combinations thereof.

In one or more embodiments, selective deposition is performed by introducing a hydrogen-containing precursor by utilizing a conductively coupled plasma (CCP) deposition. In one or more embodiments, selective deposition includes introducing a hydrogen-containing precursor and a metal-containing precursor with the carrier gas. In one or more embodiments, the metal-containing precursor gas may be fluorine free to prevent formation of metal fluoride solids that have undesirable resistivity properties. The hydrogen-containing precursor can include molecular hydrogen (H₂) and the metal-containing precursor is titanium chloride (TiCl₄). Without being bound by theory, the introduction of both the hydrogen-containing and the metal-containing precursors into the carrier gas causes both precursors to become energized on a molecular level to a point of at least partial disassociation in the carrier gas. For example, titanium chloride may disassociate into titanium-based ions (Ti⁺, TiClₓ⁺) or free radial titanium trichloride (TiCl₃⁺); hydrogen may disassociate into hydronium ions (H⁺) or hydrogen free radicals (H*). The dissociated species may then interact with the silicon surface of the silicon-containing contact, donate electrons to the silicon atoms and then each species interact with one another and form the titanium silicide layer on the top of the silicon-based portion 304.

In one or more embodiments, the selective deposition is performed by maintaining the semiconductor substrate at a first metal deposition temperature. In one or more embodiments, the semiconductor substrate is maintained at a metal deposition temperature of about 200° C. to 800° C., such as about 200° C., 300° C., 400° C., 450° C., and 500° C. to about 600° C., 700° C., and 800° C., for a period of about 5 seconds to about 20 seconds, in which an inert gas may be present. The inert gas flowing over the semiconductor substrate may facilitate in cooling and affixing the deposition material (e.g., TiSi) on the top of the silicon-containing contact as well as removing volatilized products and unreacted materials, such as molecular hydrogen and hydrogen chloride (HCl).

At operation 430, optionally, the titanium containing layer 308 is exposed to ambient pressure, e.g., performing a vacuum break. Without being bound by theory, the oxidized titanium containing layer 308 may protect the titanium containing layer 308 from oxidizing

At operation 440, the titanium containing layer 308 is exposed to a gradient oxidation process, as shown in FIG. 5C. The gradient oxidation process oxidizes portions of the titanium containing layer 308 to form an oxidized titanium containing layer 502.

In some examples, the gradient oxidation process includes the use of an O₂ inductively coupled plasma (ICP) that includes a limited gas flow to create an oxygen starvation reaction mode on the titanium containing layer 308. The O₂ ICP provides a low power O₂ plasma with a high ion/radical ratio, which can enhance the field oxidation and deactivate the reactive species before reaching the titanium containing layer 308 over the bottom surface 326. In this mode, the field region 322 and sidewalls 324a and 324b are oxidized, or more heavily oxidized, which allows for preferential etching of the oxidized regions of the oxidized TiSi layer, while maintaining the titanium containing layer 308 along the bottom surface 326. In one example, the oxidation of the titanium containing layer 308 has a selectivity at the field region 322 that is seven times greater than the selectivity at the bottom surface 326. Thus, the oxidized TiSi layer is preferentially formed at in the field region 322. In one example, the gradient oxidation of titanium containing layer 308 results in the formation of the oxidized TiSi layer.

In some embodiments, the gradient oxidation process includes a reduction process followed by an oxidation process. In some embodiments, the gradient oxidation process includes the oxidation process without the reduction process. The reduction process includes exposing the substrate to a reducing gas, for example, hydrogen. The oxidation process includes exposing the substrate to an oxidizing gas, for example, oxygen. In some embodiments, during the reduction process, the processing region is maintained at a pressure of less than about 120 mTorr, such as in a range from about 50 mTorr to about 110 mTorr, in a range from about 60 mTorr to about 100 Torr, or for example, in a range from about 70 mTorr to about 90 mTorr. Exposing the semiconductor device structure to the reducing gas includes flowing the reducing gas into the processing region at a flow rate of about 200 sccm or less, such as in a range from about 100 sccm to about 170 sccm, or in a range from about 120 sccm to about 80 sccm. Exposing the semiconductor device structure to the reducing agent may further include flowing a carrier gas, for example, an inert gas such as argon into the processing region at a flow rate of about 300 sccm or less, such as in a range from about 100 sccm to about 200 sccm, or in a range from about 120 sccm to about 150 sccm. During the reduction process, the semiconductor device structure may be maintained at a temperature of about 250 degrees Celsius or less, such as in a range from about 0 degrees Celsius to about 250 degrees Celsius, in a range from about 250 degrees Celsius to about 400 degrees Celsius, or for example, in a range from about 300 degrees Celsius to about 350 degrees Celsius. During the reduction process, ICP plasma power of 2000 Watts or less, such as in a range from about 500 Watts to 1500 Watts, or for example, in a range from about 850 Watts to about 1000 Watts is applied to maintain the plasma. The reduction process may be performed for a time period of 60 seconds or less, such as in a range from about 10 seconds to about 40 seconds, or for example, in a range from about 10 seconds to about 30 seconds.

In some embodiments, during the oxidation process, the processing region is maintained at a pressure of less than about 40 mTorr, such as in a range from about 1 mTorr to about 5 mTorr, or for example, in a range from about 1 mTorr to about 2 mTorr. Exposing the titanium containing layer 308 to the oxidizing gas includes flowing the oxidizing gas into the processing region at a flow rate of about 20 sccm or less, such as in a range from about 1 sccm to about 10 sccm, or in a range from about 1 sccm to about 5 sccm. Exposing the titanium containing layer 308 to the reducing agent may further include flowing a carrier gas, for example, an inert gas such as argon into the processing region at a flow rate of about 100 sccm or less, such as in a range from about 50 sccm to about 100 sccm, or in a range from about 50 sccm to about 100 sccm. During the oxidation process, the semiconductor device structure may be maintained a temperature of about 450 degrees Celsius or less, such as in a range from about 0 degrees Celsius to about 250 degrees Celsius. During the oxidation process, ICP plasma power of 300 Watts or less, such as in a range from about 100 Watts to 300 Watts, or for example, in a range from about 180 Watts to about 210 Watts. The oxidation process may be performed for a time period of 60 seconds or less, such as in a range from about 10 seconds to about 40 seconds, or for example, in a range from about 12 seconds to about 30 seconds.

In some embodiments, the oxidation process is performed at a pressure in a range from about 2 mTorr to about 7 mTorr, at an ICP power in a range from about 210 Watts to about 350 Watts, at a flow rate of argon gas into the processing region in a range from about 900 sccm to about 1000 sccm, at a flow rate of oxygen gas into the processing region in a range from about 5 sccm to about 10 sccm, at a temperature in a range from about 0 degrees Celsius to about 250 degrees Celsius, and for a time period from about 90 seconds to about 180 seconds.

At operation 450, a selective etch process is performed to remove the oxidized titanium containing layer 502, thereby exposing the titanium containing layer 308, e.g., an etch back process, as shown in FIG. 5D. The selective etch process selectively targets the oxidized titanium containing layer 502. The selective etch process includes flowing an etching gas and optional inert gas into the processing region. The etching gas can include chlorine or fluorine containing gas, or a combination thereof, wherein the etchant is selected to be reactive to the oxidized titanium containing layer, over the non-oxide metal, e.g., the substrate 302. In some embodiments, the etching gas may include WF₆, WOCl₄, WO₂Cl₂, WCl₅, WCl₆, BCl₃, Cl₂, or other suitable compound. In some embodiments, the selective etch process is performed at a pressure in a range from about 5 mTorr to about 20 mTorr, at an ICP power in a range from about 300 Watts to about 500 Watts, at a flow rate of argon gas into the processing region in a range from about 180 sccm to about 500 sccm, at a flow rate of WF₆ gas into the processing region in a range from about 5 sccm to about 10 sccm, at a temperature in a range from about 250 degrees Celsius to about 350 degrees Celsius, and for a time period from about 15 seconds to about 240 seconds.

The selective etch process exposes the oxidized titanium containing layer 502 to an etchant process to selectively remove the oxidized titanium containing layer 502 with minimal removal of the underlying titanium containing layer 308. The selective etch process may be a cyclic process. The selective etch process may be repeated for a number of cycles sufficient to reduce the thickness of the oxidized titanium containing layer 502 from the initial thickness to a targeted reduced thickness and/or elimination. For example, the selective etch process may be repeated for two to four cycles, for example, two cycles. The selective etch process of operation 450 may be repeated until the oxidized titanium containing layer 502 is eliminated.

The thickness of the oxidized titanium containing layer 502 formed over the field region is reduced at a greater rate than a thickness of the oxidized titanium containing layer 502 formed over the sidewall surfaces and the bottom surfaces of the cavity 310. Additionally, the thickness of the oxidized titanium containing layer 502 formed over the sidewalls 324a and 324b are reduced at a greater rate than a thickness of the oxidized titanium containing layer 502 formed over the bottom surface 326.

At operation 460, a metal cap 312 is deposited on the titanium containing layer 308 on the silicon-based portion 304, as shown in FIG. 5E. In some embodiments, the metal cap 312 has an average thickness of about 2.5 nm to about 11 nm, such as about 6 nm to about 9 nm, such as about 8 nm. The metal cap 312 can be deposited by any suitable deposition process, such as CVD or ALD. The metal cap 312 may be deposited using a partially selective deposition process that is a fluorine free metal deposition process of the metal material used for forming the metal cap 312. In some embodiments, the metal cap 312 may be formed of tungsten. In some embodiments, the metal cap 312 may be formed of molybdenum.

The metal cap 312 can include cobalt (Co), molybdenum (Mo), tungsten (W), tantalum (Ta), titanium (Ti), ruthenium (Ru), rhodium (Rh), copper (Cu), iron (Fe), manganese (Mn), vanadium (V), niobium (Nb), hafnium (Hf), zirconium (Zr), yttrium (Y), aluminum (AI), tin (Sn), chromium (Cr), lanthanum (La), iridium (Ir), or combinations thereof. In some embodiments, the metal cap 312 may be formed of tungsten. In some embodiments, the metal cap 312 may be formed of molybdenum. In some embodiments, for example, a metal cap provides metal seeding on a bottom of the cavity 310 (e.g., SiO₂ or SiN surface).

As part of a process of depositing the metal cap 312 onto the titanium containing layer 308 during operation 460, both a metal-containing precursor and a reducing agent are introduced in the process chamber with a carrier gas to form a gas mixture. The gas mixture is then introduced towards the surface of the substrate 302. The carrier gas may include a noble gas, such as argon, neon, and helium, and combinations thereof.

As part of a process of depositing the metal cap 312 onto the titanium containing layer 308, the substrate 302 may be maintained at a metal deposition temperature. In one or more embodiments, the substrate 302 is maintained at a metal deposition temperature of about 300° C. to 550° C., such as from about 300° C., 325° C., 350° C., 375° C., 400° C., 425° C., 450° C., 475° C., to about 475° C., about 500° C., about 525° C. or 550° C., such as about 450° C. to about 470° C. In one or more embodiments, a chamber pressure at which the partially selective metal deposition process is performed is about 50 T to about 150 T, such as about 80 T to about 120 T, such as about 80 T to about 100 T, alternatively about 100 T to about 120 T. In one or more embodiments, the period of time at which the metal deposition process is performed is about 5 seconds to about 45 seconds, such as about 30 seconds or less, such as about 10 seconds to about 25 seconds. In one or more embodiments, both the TiSi deposition process and the metal deposition process occur in the same process chamber or in different process chambers.

The metal cap 312 may utilize a metal-containing precursor, such as a fluorine free second metal-containing precursor. In one or more embodiments, the introduced metal-containing precursor includes a fluorine-free metal halide. For example, the metal-containing precursor may include a fluorine-free tungsten precursor (FFW). Examples of FFW halides can include tungsten pentachloride (WCl₅), tungsten hexachloride (WCl₆), or combinations thereof. In one or more embodiments, the fluorine-free tungsten precursor includes a tungsten oxyhalide precursor. Examples of a tungsten oxyhalide can include tungsten oxytetrachloride (WOCl₄), tungsten dichloride dioxide (WO₂Cl₂), or combinations thereof. In one or more embodiments, the fluorine-free tungsten precursor is also a chlorine-free tungsten precursor (CFW). Examples of a fluorine-free and chloride-free tungsten precursor can include tungsten pentabromide (WBr₅), tungsten hexabromide (WBr₆), or combinations thereof. In one or more embodiments, the metal-containing precursor includes a fluorine-free metal organic, such as tris(3-hexyne) tungsten carbonyl (W(CO)(CH₃CH₂C≡CCH₂CH₃)₃).

As part of the process of depositing a metal cap 312 onto the titanium containing layer 308 at operation 460, a reducing agent that is reactive with a metal-containing precursor is introduced into the carrier gas along with the metal-containing precursor. The reducing agent may be a hydrogen-containing composition, such as molecular hydrogen (H₂). The reducing agent acts as a proton donor to cause the metal-containing precursor to form a metallic film comprising the metal on top of the TiSi layer.

Operation 460 may include maintaining a flow rate of the metal-containing precursor to a flow rate of the reducing agent into the carrier gas until a metal cap 312 forms on the titanium containing layer 308. In one or more embodiments, reducing agent (e.g., H₂) is provided to the chamber at a flow rate of about 10 slm or greater, such as about 10 slm to about 100 slm, such as about 15 slm to about 50 slm. In one or more embodiments, the metal-containing precursor is provided to the chamber at an ampoule temperature of about 60° C. or greater and a flow rate of about 0.5 slm to about 2 slm, such as about 0.8 slm to about 1.2 slm. In one or more embodiments, the metal-containing precursor and the reducing agent are introduced (into the carrier gas) at a molar ratio of about 10:1 to 1:100, such as about 10:1, 5:1, 2:1, and 1:1 to about 1:2, 1:5, 1:10, 1:20, 1:50, and 1:100. In one or more embodiments, the combined flow rates of metal-containing precursor and reducing agent are in a range of from about 1 vol. % to 70 vol. % of the overall gas mixture, where the remainder of the gas mixture includes the carrier gas.

At high-pressure, high flow conditions, the deposition rate of the metal cap is high over the titanium containing layer 308. Such conditions can cause selectivity loss at the sidewalls 324a, 324b, and the bottom surface 326. Without being bound by theory, the mechanism of selectivity loss is believed to provide higher concentration of reaction byproduct formed at the TiSi interface. Under high pressure where diffusion is limited, such byproduct will not be easily removed from the cavity 310 but will adsorb to sidewalls of the cavity in a bottom to top direction. These adsorbed metal byproducts will act as nucleation centers for metal cap growth. For example, if deposition time is long enough, selectivity will occur from bottom to top trench creating a V-shape profile of the metal cap 312.

In one or more embodiments, the process of depositing a metal cap 312 onto the titanium containing layer 308, such as operation 460, includes introducing an inert gas to the partially selective metal cap deposited semiconductor substrate. The inert gas evacuates the carrier gas, reactants, and products from the partially selective metal cap deposited semiconductor substrate and process chamber used to form the metal cap deposited semiconductor.

In block 470, a material 328, e.g., metal gapfill material, is deposited in a bottom-up selective process (e.g., a tungsten hexafluoride (WF₆) based selective process (tungsten over dielectric material of the sidewalls 324a, 324b of the cavity 310, etc.)), as shown in FIG. 5F. In some embodiments, a conformal gapfill may be used instead of a bottom-up fill. In some embodiments, for example, the cavity 310 may be filled by conformal CVD using tungsten or molybdenum and the like. In some embodiments, a conformal molybdenum fill can be performed by using MoO₂Cl₂ or MoOCl₄+H₂ processes or a mixture of MoCl₅ with the aforementioned two precursors.

As stated previously, in addition to tungsten as a TiSi capping layer, molybdenum (Mo) can be used as a capping material as well by selective Mo process. Similarly, the structure fill can be done by selective Mo fill or conformal Mo fill. In some embodiments, Mo and W materials can be interchanged or mixture of Mo and W used.

In FIG. 5F, a resultant conformal metal gap fill material 328 has been conformally deposited into cavity 310. In FIG. 5F, metal gap fill material 328 is shown filling the cavity 310. The metal gap fill material 328 is shown in contact with the partially selective metal cap such that the metal gap fill material 328 is in electrical communication with the contact structure, e.g., silicon-based portion 304. The metal gap fill material 328 is also in contact with at least a portion of the sidewalls 324a, 324b.

Any suitable chemical deposition process, including but not limited to CVD or ALD processes, may be utilized for the metal gap fill material process. The metal gap fill material may be applied such that the material is deposited onto the bottom portion of the device feature and then grown upwards towards the semiconductor field region such that the resultant gap fill material at least approaches the field region (as shown in FIG. 3E) or is at least partially level with the field region (not shown).

In one or more embodiments, the metal gap fill material includes one or more of cobalt (Co), molybdenum (Mo), tungsten (W), tantalum (Ta), titanium (Ti), ruthenium (Ru), rhodium (Rh), copper (Cu), iron (Fe), manganese (Mn), vanadium (V), niobium (Nb), hafnium (Hf), zirconium (Zr), yttrium (Y), aluminum (AI), tin (Sn), chromium (Cr), lanthanum (La), iridium (Ir), or any combination thereof. In one or more embodiments, the metal gap fill material includes tungsten (e.g., deposited using WF₆). In one or more embodiments, the conductor material includes molybdenum.

In the method 600 of FIG. 6, a selective CVD TiSi deposition and TiSi/W integration flow is shown. In the discussion of the method 600, references will be made to FIGS. 7A-7H. At operation 602, a preclean process is performed to remove any contaminates and/or oxidation from surfaces of a contact structure as depicted in FIG. 7A. The contact structure has a silicon-based portion 704 that is exposed in a cavity 710 of a substrate 702 formed of a dielectric material (e.g., silicon dioxide, silicon nitride, etc.). In some embodiments, the silicon-based portion 304 may be a silicon material or a silicon germanium (SiGe) material.

In one or more embodiments, cavities (e.g., vias) can have an average width. For example, cavity 710 can have a width (shown in FIG. 7A) of about 35 nanometers (nm) or less, such as about 5 nm to about 35 nm, such as about 5 nm, 10 nm, and 15 nm to about 20 nm, 25 nm, 30 nm, or 35 nm. In one or more embodiments, cavity 310 can have an aspect ratio (depth:width) of about 1:1 to about 100:1, such as about 10:1, 15:1, or 25:1 to about 35:1, 45:1, or 50:1.

At operation 604, a titanium layer deposition process is performed to produce a titanium containing layer 706 on the silicon-based portion 704 as depicted in FIG. 7B. For example, the titanium containing layer can include a Ti layer, and/or a TiSi layer. TiSi is TiₓSi_{y} which may include Ti₅Si₃, TiSi₂, TiSi, or combinations thereof. The process is selective to the silicon-based portion 704 over the dielectric material of the substrate 702, but a thin titanium containing layer may also form on the surfaces of the field region 722 of the substrate 702 and on sidewalls 724a, 724b in the cavity 710, including a bottom surface 726 of the cavity 710. In some embodiments, the selective deposition process is a CVD TiSi process, e.g., a plasma enhanced CVD process (PECVD), with selectivity on silicon (Si) or silicon germanium (SiGe) over oxide/SiN of approximately greater than 30:1 (vol/vol). The selective deposition process can provide a thickness of TiSi of approximately 3 nm to approximately 9 nm on the silicon-based portion 704, in which a selectivity loss on the field region 722 or sidewalls 724a, 724b and the bottom surface 726 of the cavity 710 is generally less than approximately 1 angstrom to approximately 30 angstroms.

Selective TiSi deposition can be performed using any suitable CVD or ALD process. In some embodiments, the CVD or ALD process includes utilizing a plasma with a carrier gas. The plasma/carrier gas may then be introduced towards the surface of the semiconductor substrate. In one or more embodiments, the carrier gas includes a noble gas, such as argon, neon, helium, or combinations thereof.

In one or more embodiments, selective deposition is performed by introducing a hydrogen-containing precursor by utilizing a conductively coupled plasma (CCP) deposition. In one or more embodiments, selective deposition includes introducing a hydrogen-containing precursor and a metal-containing precursor with the carrier gas. In one or more embodiments, the metal-containing precursor gas may be fluorine free to prevent formation of metal fluoride solids that have undesirable resistivity properties. The hydrogen-containing precursor can include molecular hydrogen (H₂) and the metal-containing precursor is titanium chloride (TiCl₄). Without being bound by theory, the introduction of both the hydrogen-containing and the metal-containing precursors into the carrier gas causes both precursors to become energized on a molecular level to a point of at least partial disassociation in the carrier gas. For example, titanium chloride may disassociate into titanium-based ions (Ti⁺, TiClₓ⁺) or free radial titanium trichloride (TiCl₃⁺); hydrogen may disassociate into hydronium ions (H⁺) or hydrogen free radicals (H*). The dissociated species may then interact with the silicon surface of the silicon-containing contact, donate electrons to the silicon atoms and then each species interact with one another and form the titanium silicide layer on the top of the silicon-based portion 704.

In one or more embodiments, the selective deposition is performed by maintaining the semiconductor substrate at a first metal deposition temperature. In one or more embodiments, the semiconductor substrate is maintained at a metal deposition temperature of about 200° C. to 800° C., such as about 200° C., 300° C., 400° C., 450° C., and 500° C. to about 600° C., 700° C., and 800° C., for a period of about 100 seconds to about 1000 seconds, in which an inert gas may be present. The inert gas flowing over the semiconductor substrate may facilitate in cooling and affixing the deposition material (e.g., TiSi) on the top of the silicon-containing contact as well as removing volatilized products and unreacted materials, such as molecular hydrogen and hydrogen chloride (HCl).

At operation 606, a first selective capping layer deposition process is performed to deposit or produce a nitrogen containing layer 708 over the titanium containing layer 706 on the silicon-based portion 704 as depicted in FIG. 7C. The nitrogen containing layer 708 may be a capping layer. For example, the nitrogen containing layer can include a TiN layer and/or a TiSiN layer. In one or more embodiments the process is selective to the titanium containing layer 706 over the dielectric material of the substrate 702. A thin nitrogen containing layer 708 may also form on the surfaces of the field region 722 of the substrate 702 and on sidewalls 724a, 724b in the cavity 710, including a bottom surface 726 of the cavity 710. In some embodiments, the selective deposition process is a CVD TiN process, e.g., a plasma enhanced CVD process (PECVD). The selective deposition process can provide a thickness of TiN of approximately 3 nm to approximately 9 nm on the silicon-based portion 704, in which a selectivity loss on the field region 722 or sidewalls 724a, 724b and the bottom surface 726 of the cavity 710 is generally less than approximately 10 angstrom to approximately 30 angstroms. In one or more embodiments, the first selective capping layer is non-selective. The non-selective deposition process is a ALD TiN process.

Selective TiN deposition can be performed using any suitable CVD, PE-CVD, or ALD process. In some embodiments, the CVD, PE-CVD, or ALD process includes utilizing a plasma with a carrier gas. The plasma/carrier gas may then be introduced towards the surface of the semiconductor substrate. In one or more embodiments, the carrier gas includes a noble gas, such as argon, neon, helium, or combinations thereof.

In one or more embodiments, selective deposition is performed by introducing a hydrogen-containing precursor by utilizing a conductively coupled plasma (CCP) deposition. In one or more embodiments, selective deposition includes introducing a hydrogen-containing precursor, a nitrogen containing precursor, and a metal-containing precursor with the carrier gas. In one or more embodiments, the metal-containing precursor gas may be fluorine free to prevent formation of metal fluoride solids that have undesirable resistivity properties. The hydrogen-containing precursor can include molecular hydrogen (H₂), the nitrogen containing precursor is nitrogen (N₂), or ammonia (NH₄) and the metal-containing precursor is titanium chloride (TiCl₄). Without being bound by theory, the introduction of the hydrogen-containing, the nitrogen-containing, and the metal-containing precursors into the carrier gas causes both precursors to become energized on a molecular level to a point of at least partial disassociation in the carrier gas.

In one or more embodiments, the selective deposition is performed by maintaining the semiconductor substrate at a first metal deposition temperature. In one or more embodiments, the semiconductor substrate is maintained at a metal deposition temperature of about 200° C. to 800° C., such as about 200° C., 300° C., 400° C., 450° C., and 500° C. to about 600° C., 700° C., and 800° C., for a period of about 5 seconds to about 20 seconds, in which an inert gas may be present. The inert gas flowing over the semiconductor substrate may facilitate in cooling and affixing the deposition material (e.g., TiN) on the top of the first capping layer as well as removing volatilized products and unreacted materials, such as molecular hydrogen and hydrogen chloride (HCl).

Additionally or alternatively, at operation 606, the first selective capping layer is formed by a chemical modification process. For example, a chemical modification process is performed on the titanium containing layer 706 to produce a nitrided layer (a nitrogen containing layer 708), e.g., a TiSiN layer over the titanium containing layer 706, as shown in FIG. 7C. The chemical modification process can include a nitridation process via flowing a nitrogen based gas (N₂), hydrogen (H₂), a nitrogen radical such as an ammonia radical, and/or a nitrogen based compound such as ammonia over the titanium containing layer 706 to convert the titanium containing layer 706 into a nitrided layer (e.g., the nitrogen containing layer 708). The chemical modification process can include flowing 500 sccm to about 6000 sccm of nitrogen gas (e.g., ammonia) over the titanium containing layer 706.

At operation 608, optionally, the nitrogen containing layer 708 is exposed to ambient pressure, e.g., performing a vacuum break. Without being bound by theory, the nitrided titanium containing layer may protect the titanium containing layer 706 from oxidizing.

At operation 610, a selective etch process is performed to remove at least a portion of the nitrogen containing layer 708, e.g., an etch back process, as shown in FIGS. 7D and 7F. The selective etch process selectively targets the nitrogen containing layer 708, e.g., a TiN layer. The selective etch process includes flowing an etching gas and optional inert gas into the processing region. The etching gas can include chlorine or fluorine containing gas, or a combination thereof, wherein the etchant is selected to be reactive to the oxidized titanium containing layer, over the non-oxide metal, e.g., the substrate 702. In some embodiments, the etching gas may include WF₆, WOCl₄, WO₂Cl₂, WCl₅, WCl₆, BCl₃, Cl₂, or other suitable compound. In some embodiments, the selective etch process is performed at a pressure in a range from about 5 mTorr to about 20 mTorr, at an ICP power in a range from about 100 Watts to about 500 Watts, at a flow rate of argon gas into the processing region in a range from about 180 sccm to about 500 sccm, at a flow rate of WF₆ gas into the processing region in a range from about 5 sccm to about 10 sccm, at a temperature in a range from about 250 degrees Celsius to about 350 degrees Celsius, and for a time period from about 15 seconds to about 240 seconds.

In one or more embodiments, the selective etch process exposes the nitrogen containing layer 708 to an etchant process to selectively remove the nitrogen containing layer 708 with minimal removal of the underlying titanium containing layer 706. The selective etch process may be a cyclic process. The selective etch process may be repeated for a number of cycles sufficient to reduce the thickness of the nitrogen containing layer 708 from the initial thickness to a targeted reduced thickness and/or elimination. For example, the selective etch process may be repeated for two to twelve cycles, for example, eight cycles. For example, in one or more embodiments, as shown in FIG. 7D, the selective etch process of operation 610 is repeated until the nitrogen containing layer 708 is eliminated. For example, in one or more embodiments, as shown in FIG. 7F, the selective etch process of operation 610 is repeated until the nitrogen containing layer 708 is reduced to a desired thickness or area. For example, as shown in FIG. 7F, the nitrogen containing layer 708 is reduced along the field region 722 and the sidewalls 724a, 724b.

The thickness of the nitrogen containing layer 708 formed over the field region is reduced at a greater rate than a thickness of the nitrogen containing layer 708 formed over the sidewall surfaces and the bottom surfaces of the cavity 710. Additionally, the thickness of the nitrogen containing layer 708 formed over the sidewalls 724a and 724b are reduced at a greater rate than a thickness of the nitrogen containing layer 708 formed over the bottom surface 726.

At operation 612, a second selective capping layer deposition process is performed. In one or more embodiments, as shown in FIG. 7E, a metal cap 712 is deposited on the titanium containing layer 706 on the silicon-based portion 704. In one or more embodiments, as shown in FIG. 7G, the metal cap 712 is deposited on the nitrogen containing layer 708. In some embodiments, the metal cap 712 has an average thickness of about 2.5 nm to about 11 nm, such as about 6 nm to about 9 nm, such as about 8 nm. The metal cap 712 can be deposited by any suitable deposition process, such as CVD or ALD. The metal cap 712 may be deposited using a partially selective deposition process that is a fluorine free metal deposition process of the metal material used for forming the metal cap 712. In some embodiments, the metal cap 712 may be formed of tungsten. In some embodiments, the metal cap 712 may be formed of molybdenum.

The metal cap 712 can include cobalt (Co), molybdenum (Mo), tungsten (W), tantalum (Ta), titanium (Ti), ruthenium (Ru), rhodium (Rh), copper (Cu), iron (Fe), manganese (Mn), vanadium (V), niobium (Nb), hafnium (Hf), zirconium (Zr), yttrium (Y), aluminum (AI), tin (Sn), chromium (Cr), lanthanum (La), iridium (Ir), or combinations thereof. In some embodiments, the metal cap 712 may be formed of tungsten. In some embodiments, the metal cap 712 may be formed of molybdenum. In some embodiments, for example, a metal cap provides metal seeding on a bottom of the cavity 710 (e.g., SiO₂ or SiN surface).

As part of a process of depositing the metal cap 712 onto the titanium containing layer 706 or the nitrogen containing layer 708, during operation 612, both a metal-containing precursor and a reducing agent are introduced in the process chamber with a carrier gas to form a gas mixture. The gas mixture is then introduced towards the surface of the substrate 702. The carrier gas may include a noble gas, such as argon, neon, and helium, and combinations thereof.

As part of a process of depositing the metal cap 712 onto the titanium containing layer 706 or the nitrogen containing layer 708, the substrate 702 may be maintained at a metal deposition temperature. In one or more embodiments, the substrate 702 is maintained at a metal deposition temperature of about 300° C. to 475° C., such as from about 300° C., 325° C., 350° C., 375° C., 400° C., 425° C., 450° C., and 475° C. In one or more embodiments, a chamber pressure at which the partially selective metal deposition process is performed is about 10 T to about 150 T, such as about 80 T to about 120 T, such as about 80 T to about 100 T, alternatively about 100 T to about 120 T. In one or more embodiments, the period of time at which the metal deposition process is performed is about 300 seconds to about 3600 seconds, such as about 600 seconds or less, such as about 1000 seconds to about 2500 seconds. In one or more embodiments, both the TiSi deposition process and the metal deposition process occur in the same process chamber or in different process chambers.

The metal cap 712 may utilize a metal-containing precursor, such as a fluorine free second metal-containing precursor. In one or more embodiments, the introduced metal-containing precursor includes a fluorine-free metal halide. For example, the metal-containing precursor may include a fluorine-free tungsten precursor (FFW). Examples of FFW halides can include tungsten pentachloride (WCl₅), tungsten hexachloride (WCl₆), or combinations thereof. In one or more embodiments, the fluorine-free tungsten precursor includes a tungsten oxyhalide precursor. Examples of a tungsten oxyhalide can include tungsten oxytetrachloride (WOCl₄), tungsten dichloride dioxide (WO₂Cl₂), or combinations thereof. In one or more embodiments, the fluorine-free tungsten precursor is also a chlorine-free tungsten precursor (CFW). Examples of a fluorine-free and chloride-free tungsten precursor can include tungsten pentabromide (WBr₅), tungsten hexabromide (WBr₆), or combinations thereof. In one or more embodiments, the metal-containing precursor includes a fluorine-free metal organic, such as tris(3-hexyne) tungsten carbonyl (W(CO)(CH₃CH₂C≡CCH₂CH₃)₃).

As part of the process of depositing a metal cap 712 onto the titanium containing layer 706 or the nitrogen containing layer 708, at operation 612, a reducing agent that is reactive with a metal-containing precursor is introduced into the carrier gas along with the metal-containing precursor. The reducing agent may be a hydrogen-containing composition, such as molecular hydrogen (H₂). The reducing agent acts as a proton donor to cause the metal-containing precursor to form a metallic film comprising the metal on top of the TiSi layer.

Operation 612 may include maintaining a flow rate of the metal-containing precursor to a flow rate of the reducing agent into the carrier gas until a metal cap 712 forms on the titanium containing layer 706 or the nitrogen containing layer 708. In one or more embodiments, reducing agent (e.g., H₂) is provided to the chamber at a flow rate of about 10 slm or greater, such as about 10 slm to about 100 slm, such as about 15 slm to about 50 slm. In one or more embodiments, the metal-containing precursor is provided to the chamber at an ampoule temperature of about 50° C. or greater and a flow rate of about 0.5 slm to about 2 slm, such as about 0.8 slm to about 1.2 slm. In one or more embodiments, the metal-containing precursor and the reducing agent are introduced (into the carrier gas) at a molar ratio of about 10:1 to 1:100, such as about 10:1, 5:1, 2:1, and 1:1 to about 1:2, 1:5, 1:10, 1:20, 1:50, and 1:100. In one or more embodiments, the combined flow rates of metal-containing precursor and reducing agent are in a range of from about 1 vol. % to 70 vol. % of the overall gas mixture, where the remainder of the gas mixture includes the carrier gas.

At high-pressure, high flow conditions, the deposition rate of the metal cap is high over the titanium containing layer 706 or the nitrogen containing layer 708. Such conditions can cause selectivity loss at the sidewalls 724a, 724b, and the bottom surface 726. Without being bound by theory, the mechanism of selectivity loss is believed to provide higher concentration of reaction byproduct formed at the TiSi interface. Under high pressure where diffusion is limited, such byproduct will not be easily removed from the cavity 710 but will adsorb to sidewalls of the cavity in a bottom to top direction. These adsorbed metal byproducts will act as nucleation centers for metal cap growth. For example, if deposition time is long enough, selectivity will occur from bottom to top trench creating a V-shape profile of the metal cap 712.

In one or more embodiments, the process of depositing a metal cap 712 onto the titanium containing layer 706 or the nitrogen containing layer 708, such as operation 614, includes introducing an inert gas to the partially selective metal cap deposited semiconductor substrate. The inert gas evacuates the carrier gas, reactants, and products from the partially selective metal cap deposited semiconductor substrate and process chamber used to form the metal cap deposited semiconductor.

At operation 614, a material 728, e.g., metal gapfill material, is deposited in a bottom-up selective process (e.g., a tungsten hexafluoride (WF₆) based selective process (tungsten over dielectric material of the sidewalls 724a, 724b of the cavity 710, etc.)), as shown in FIG. 7H. In some embodiments, a conformal gapfill may be used instead of a bottom-up fill. In some embodiments, for example, the cavity 710 may be filled by conformal CVD using tungsten or molybdenum and the like. In some embodiments, a conformal molybdenum fill can be performed by using MoO₂Cl₂ or MoOCl₄+H₂ processes or a mixture of MoCl₅ with the aforementioned two precursors.

As stated previously, in addition to tungsten as a TiSi capping layer, molybdenum (Mo) can be used as a capping material as well by selective Mo process. Similarly, the structure fill can be done by selective Mo fill or conformal Mo fill. In some embodiments, Mo and W materials can be interchanged or mixture of Mo and W used.

In FIG. 7H, a resultant conformal metal gap fill material 728 has been conformally deposited into cavity 710. In FIG. 7H, metal gap fill material 728 is shown filling the cavity 710. The metal gap fill material 728 is shown in contact with the partially selective metal cap such that the metal gap fill material 728 is in electrical communication with the contact structure, e.g., silicon-based portion 704. The metal gap fill material 728 is also in contact with at least a portion of the sidewalls 724a, 724b.

Any suitable deposition process, including but not limited to CVD or ALD processes, may be utilized for the metal gap fill material process. The metal gap fill material may be applied such that the material is deposited onto the bottom portion of the device feature and then grown upwards towards the semiconductor field region such that the resultant gap fill material at least approaches the field region (as shown in FIG. 7H) or is at least partially level with the field region (not shown).

In one or more embodiments, the metal gap fill material includes one or more of cobalt (Co), molybdenum (Mo), tungsten (W), tantalum (Ta), titanium (Ti), ruthenium (Ru), rhodium (Rh), copper (Cu), iron (Fe), manganese (Mn), vanadium (V), niobium (Nb), hafnium (Hf), zirconium (Zr), yttrium (Y), aluminum (AI), tin (Sn), chromium (Cr), lanthanum (La), iridium (Ir), or any combination thereof. In one or more embodiments, the metal gap fill material includes tungsten (e.g., deposited using WF₆). In one or more embodiments, the conductor material includes molybdenum.

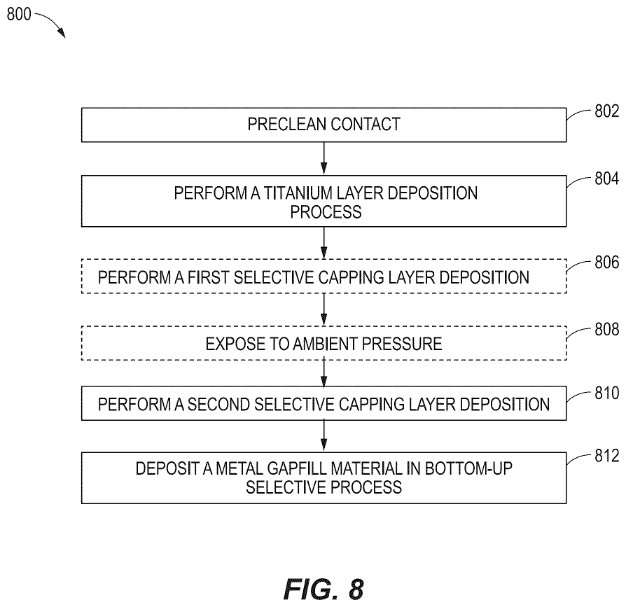

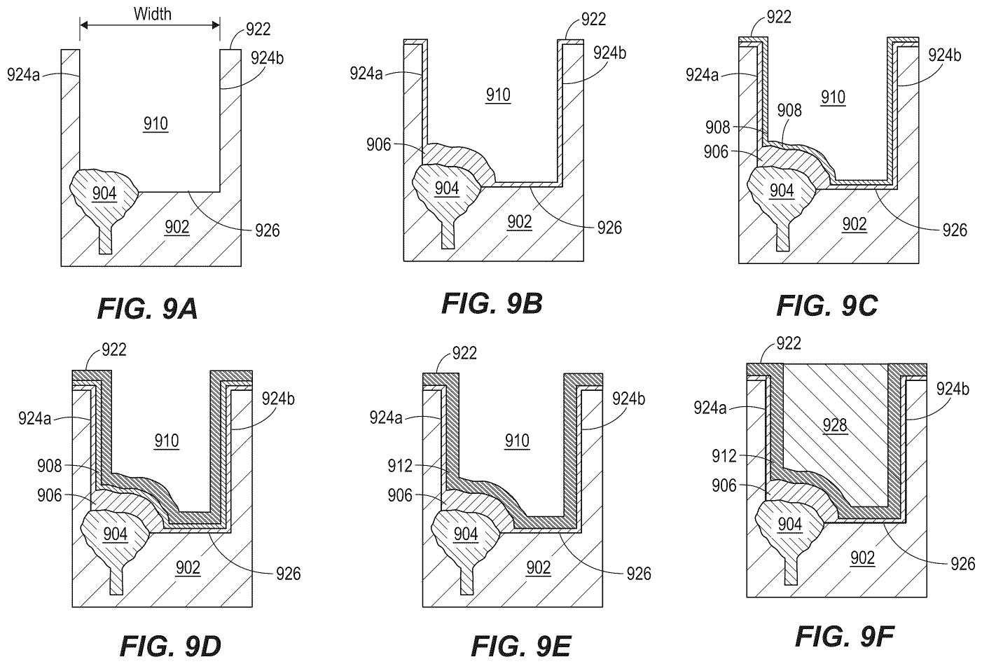

In the method 800 of FIG. 8, a selective CVD TiSi deposition and TiSi/W integration flow is shown. In the discussion of the method 800, references will be made to FIGS. 9A-9E. At operation 802, a preclean process is performed to remove any contaminates and/or oxidation from surfaces of a contact structure as depicted in FIG. 9A. The contact structure has a silicon-based portion 904 that is exposed in a cavity 910 of a substrate 902 formed of a dielectric material (e.g., silicon dioxide, silicon nitride, etc.). In some embodiments, the silicon-based portion 904 may be a silicon material or a silicon germanium (SiGe) material.

In one or more embodiments, cavities (e.g., vias) can have an average width. For example, cavity 910 can have a width (shown in FIG. 9A) of about 35 nanometers (nm) or less, such as about 5 nm to about 35 nm, such as about 5 nm, 10 nm, and 15 nm to about 20 nm, 25 nm, 30 nm, or 35 nm. In one or more embodiments, cavity 310 can have an aspect ratio (depth:width) of about 1:1 to about 100:1, such as about 10:1, 15:1, or 25:1 to about 35:1, 45:1, or 50:1.

At operation 804, a titanium layer deposition process is performed to produce a titanium containing layer 906 on the silicon-based portion 904 as depicted in FIG. 9B. For example, the titanium containing layer can include a Ti layer, and/or a TiSi layer. TiSi is TiₓSi_{y} which may include Ti₅Si₃, TiSi₂, TiSi, or combinations thereof. The process is selective to the silicon-based portion 904 over the dielectric material of the substrate 902, but a thin titanium containing layer may also form on the surfaces of the field region 922 of the substrate 902 and on sidewalls 924a, 924b in the cavity 910, including a bottom surface 926 of the cavity 910. In some embodiments, the selective deposition process is a CVD TiSi process, e.g., a plasma enhanced CVD process (PECVD), with selectivity on silicon (Si) or silicon germanium (SiGe) over oxide/SiN of approximately greater than 30:1 (vol/vol). The selective deposition process can provide a thickness of TiSi of approximately 3 nm to approximately 9 nm on the silicon-based portion 904, in which a selectivity loss on the field region 922 or sidewalls 924a, 924b and the bottom surface 926 of the cavity 910 is generally less than approximately 1 angstrom to approximately 30 angstroms.

Selective TiSi deposition can be performed using any suitable CVD or ALD process. In some embodiments, the CVD or ALD process includes utilizing a plasma with a carrier gas. The plasma/carrier gas may then be introduced towards the surface of the semiconductor substrate. In one or more embodiments, the carrier gas includes a noble gas, such as argon, neon, helium, or combinations thereof.

In one or more embodiments, selective deposition is performed by introducing a hydrogen-containing precursor by utilizing a conductively coupled plasma (CCP) deposition. In one or more embodiments, selective deposition includes introducing a hydrogen-containing precursor and a metal-containing precursor with the carrier gas. In one or more embodiments, the metal-containing precursor gas may be fluorine free to prevent formation of metal fluoride solids that have undesirable resistivity properties. The hydrogen-containing precursor can include molecular hydrogen (H₂) and the metal-containing precursor is titanium chloride (TiCl₄). Without being bound by theory, the introduction of both the hydrogen-containing and the metal-containing precursors into the carrier gas causes both precursors to become energized on a molecular level to a point of at least partial disassociation in the carrier gas. For example, titanium chloride may disassociate into titanium-based ions (Ti⁺, TiClₓ⁺) or free radial titanium trichloride (TiCl₃⁺); hydrogen may disassociate into hydronium ions (H⁺) or hydrogen free radicals (H*). The dissociated species may then interact with the silicon surface of the silicon-containing contact, donate electrons to the silicon atoms and then each species interact with one another and form the titanium silicide layer on the top of the silicon-based portion 904.

In one or more embodiments, the selective deposition is performed by maintaining the semiconductor substrate at a first metal deposition temperature. In one or more embodiments, the semiconductor substrate is maintained at a metal deposition temperature of about 200° C. to 800° C., such as about 200° C., 300° C., 400° C., 450° C., and 500° C. to about 600° C., 700° C., and 800° C., for a period of about 5 seconds to about 20 seconds, in which an inert gas may be present. The inert gas flowing over the semiconductor substrate may facilitate in cooling and affixing the deposition material (e.g., TiSi) on the top of the silicon-containing contact as well as removing volatilized products and unreacted materials, such as molecular hydrogen and hydrogen chloride (HCl).

At operation 806, an optional first selective capping layer deposition process is performed to deposit or produce a nitrogen containing layer 908 over the titanium containing layer 906 on the silicon-based portion 904 as depicted in FIG. 9C. The nitrogen containing layer 908 may be a capping layer. For example, the nitrogen containing layer can include a TiN layer, and/or a TiSiN layer. The process is selective to the titanium containing layer 906 over the dielectric material of the substrate 902, but a thin nitrogen containing layer 908 may also form on the surfaces of the field region 922 of the substrate 902 and on sidewalls 924a, 924b in the cavity 910, including a bottom surface 926 of the cavity 910. In some embodiments, the selective deposition process is a CVD TiN process, e.g., a plasma enhanced CVD process (PECVD). The selective deposition process can provide a thickness of TiN of approximately 3 nm to approximately 9 nm on the silicon-based portion 904, in which a selectivity loss on the field region 922 or sidewalls 924a, 924b and the bottom surface 926 of the cavity 910 is generally less than approximately 10 angstrom to approximately 30 angstroms.

Selective TiN deposition can be performed using any suitable CVD, PE-CVD, or ALD process. In some embodiments, the CVD, PE-CVD, or ALD process includes utilizing a plasma with a carrier gas. The plasma/carrier gas may then be introduced towards the surface of the semiconductor substrate. In one or more embodiments, the carrier gas includes a noble gas, such as argon, neon, helium, or combinations thereof.

In one or more embodiments, selective deposition is performed by introducing a hydrogen-containing precursor by utilizing a conductively coupled plasma (CCP) deposition. In one or more embodiments, selective deposition includes introducing a hydrogen-containing precursor, a nitrogen containing precursor, and a metal-containing precursor with the carrier gas. In one or more embodiments, the metal-containing precursor gas may be fluorine free to prevent formation of metal fluoride solids that have undesirable resistivity properties. The hydrogen-containing precursor can include molecular hydrogen (H₂), the nitrogen containing precursor is nitrogen (N₂), or ammonia (NH₃), and the metal-containing precursor is titanium chloride (TiCl₄). Without being bound by theory, the introduction of the hydrogen-containing, the nitrogen-containing, and the metal-containing precursors into the carrier gas causes both precursors to become energized on a molecular level to a point of at least partial disassociation in the carrier gas.

In one or more embodiments, the selective deposition is performed by maintaining the semiconductor substrate at a first metal deposition temperature. In one or more embodiments, the semiconductor substrate is maintained at a metal deposition temperature of about 200° C. to 800° C., such as about 200° C., 300° C., 400° C., 450° C., and 500° C. to about 600° C., 700° C., and 800° C., for a period of about 5 seconds to about 20 seconds, in which an inert gas may be present. The inert gas flowing over the semiconductor substrate may facilitate in cooling and affixing the deposition material (e.g., TiN) on the top of the first capping layer as well as removing volatilized products and unreacted materials, such as molecular hydrogen and hydrogen chloride (HCl).

In one or more embodiments, a chemical modification process is performed on the titanium containing layer 906 to produce a nitrided layer (a nitrogen containing layer 908) e.g., a TiSiN layer. The chemical modification process can include a nitridation process via flowing a nitrogen based gas such as ammonia or N₂, a nitrogen radical such as an ammonia radical, and/or a nitrogen based compound such as ammonia over the titanium containing layer 906 to convert the titanium containing layer 906 into a nitrided layer (a nitrogen containing layer 908). The chemical modification process can include flowing 500 sccm to about 6000 sccm of nitrogen gas, e.g., ammonia, over the titanium containing layer 906.

At operation 808, optionally, the nitrogen containing layer 908 is exposed to ambient pressure, e.g., performing a vacuum break. Without being bound by theory, the nitrided titanium containing layer may protect the titanium containing layer 906 from oxidizing. In one or more embodiments, an optional etch process (e.g., a selective etch process or a gradient etch process), as described herein, occurs to etch away at least a portion of the nitride layer (e.g., the nitrogen containing layer 908).

At operation 810, second selective capping layer deposition process is performed. The second selective capping layer is a metal cap 912. In one or more embodiments the metal cap 912 is a conformal metal gapfill material such that the metal gapfill material conforms to cavity 910. In one or more embodiments without a nitride containing layer, as shown in FIG. 9E, the metal cap 912 is deposited on the titanium containing layer 906 on the silicon-based portion 904. In one or more embodiments, as shown in FIG. 9D, the metal cap 912 is deposited on the nitrogen containing layer 908. In some embodiments, the metal cap 912 has an average thickness of about 2.5 nm to about 11 nm, such as about 6 nm to about 9 nm, such as about 8 nm. The metal cap 912 can be deposited by any suitable deposition process, such as CVD or ALD. The metal cap 912 may be deposited using a partially selective deposition process that is a fluorine free metal deposition process of the metal material used for forming the metal cap 912. In some embodiments, the metal cap 912 may be formed of tungsten. In some embodiments, the metal cap 912 may be formed of molybdenum.

The metal cap 912 can include cobalt (Co), molybdenum (Mo), tungsten (W), tantalum (Ta), titanium (Ti), ruthenium (Ru), rhodium (Rh), copper (Cu), iron (Fe), manganese (Mn), vanadium (V), niobium (Nb), hafnium (Hf), zirconium (Zr), yttrium (Y), aluminum (AI), tin (Sn), chromium (Cr), lanthanum (La), iridium (Ir), or combinations thereof. In some embodiments, the metal cap 912 may be formed of tungsten. In some embodiments, the metal cap 912 may be formed of molybdenum. In some embodiments, for example, a metal cap provides metal seeding on a bottom of the cavity 910 (e.g., SiO₂ or SiN surface).

As part of a process of depositing the metal cap 912 onto the titanium containing layer 906 or the nitrogen containing layer 908, during operation 810, both a metal-containing precursor and a reducing agent are introduced in the process chamber with a carrier gas to form a gas mixture. The gas mixture is then introduced towards the surface of the substrate 902. The carrier gas may include a noble gas, such as argon, neon, and helium, and combinations thereof.

As part of a process of depositing the metal cap 912 onto the titanium containing layer 906 or the nitrogen containing layer 908, the substrate 902 may be maintained at a metal deposition temperature. In one or more embodiments, the substrate 902 is maintained at a metal deposition temperature of about 300° C. to 475° C., such as from about 300° C., 325° C., 350° C., 375° C., 400° C., to about 425° C., 450° C., 475° C., to about 475° C. In one or more embodiments, a chamber pressure at which the partially selective metal deposition process is performed is about 50 T to about 150 T, such as about 80 T to about 120 T, such as about 80 T to about 100 T, alternatively about 100 T to about 120 T. In one or more embodiments, the period of time at which the metal deposition process is performed is about 300 seconds to about 3600 seconds, such as about 600 seconds or less, such as about 1000 seconds to about 2500 seconds. In one or more embodiments, both the TiSi deposition process and the metal deposition process occur in the same process chamber or in different process chambers.

The metal cap 912 may utilize a metal-containing precursor, such as a fluorine free second metal-containing precursor. In one or more embodiments, the introduced metal-containing precursor includes a fluorine-free metal halide. For example, the metal-containing precursor may include a fluorine-free tungsten precursor (FFW). Examples of FFW halides can include tungsten pentachloride (WCl₅), tungsten hexachloride (WCl₆), or combinations thereof. In one or more embodiments, the fluorine-free tungsten precursor includes a tungsten oxyhalide precursor. Examples of a tungsten oxyhalide can include tungsten oxytetrachloride (WOCl₄), tungsten dichloride dioxide (WO₂Cl₂), or combinations thereof. In one or more embodiments, the fluorine-free tungsten precursor is also a chlorine-free tungsten precursor (CFW). Examples of a fluorine-free and chloride-free tungsten precursor can include tungsten pentabromide (WBr₅), tungsten hexabromide (WBr₆), or combinations thereof. In one or more embodiments, the metal-containing precursor includes a fluorine-free metal organic, such as tris(3-hexyne) tungsten carbonyl (W(CO)(CH₃CH₂C≡CCH₂CH₃)₃).

As part of the process of depositing a metal cap 912 onto the titanium containing layer 906 or the nitrogen containing layer 908, at operation 810, a reducing agent that is reactive with a metal-containing precursor is introduced into the carrier gas along with the metal-containing precursor. The reducing agent may be a hydrogen-containing composition, such as molecular hydrogen (H₂). The reducing agent acts as a proton donor to cause the metal-containing precursor to form a metallic film comprising the metal on top of the TiSi layer.

Operation 810 may include maintaining a flow rate of the metal-containing precursor to a flow rate of the reducing agent into the carrier gas until a metal cap 912 forms on the titanium containing layer 906 or the nitrogen containing layer 908. In one or more embodiments, reducing agent (e.g., H₂) is provided to the chamber at a flow rate of about 10 slm or greater, such as about 10 slm to about 100 slm, such as about 15 slm to about 50 slm. In one or more embodiments, the metal-containing precursor is provided to the chamber at an ampoule temperature of about 60° C. or greater and a flow rate of about 0.5 slm to about 2 slm, such as about 0.8 slm to about 1.2 slm. In one or more embodiments, the metal-containing precursor and the reducing agent are introduced (into the carrier gas) at a molar ratio of about 10:1 to 1:100, such as about 10:1, 5:1, 2:1, and 1:1 to about 1:2, 1:5, 1:10, 1:20, 1:50, and 1:100. In one or more embodiments, the combined flow rates of metal-containing precursor and reducing agent are in a range of from about 1 vol. % to 70 vol. % of the overall gas mixture, where the remainder of the gas mixture includes the carrier gas.

At high-pressure, high flow conditions, the deposition rate of the metal cap is high over the titanium containing layer 906 or the nitrogen containing layer 908. Such conditions can cause selectivity loss at the sidewalls 924a, 924b, and the bottom surface 926. Without being bound by theory, the mechanism of selectivity loss is believed to provide higher concentration of reaction byproduct formed at the TiSi interface. Under high pressure where diffusion is limited, such byproduct will not be easily removed from the cavity 910 but will adsorb to sidewalls of the cavity in a bottom to top direction. These adsorbed metal byproducts will act as nucleation centers for metal cap growth. For example, if deposition time is long enough, selectivity will occur from bottom to top trench creating a V-shape profile of the metal cap 912.

In one or more embodiments, the process of depositing a metal cap 912 onto the titanium containing layer 906 or the nitrogen containing layer 908, such as operation 810, includes introducing an inert gas to the partially selective metal cap deposited semiconductor substrate. The inert gas evacuates the carrier gas, reactants, and products from the partially selective metal cap deposited semiconductor substrate and process chamber used to form the metal cap deposited semiconductor.

At operation 812, a material 928, e.g., metal gapfill material, is deposited in a bottom-up selective process (e.g., a tungsten hexafluoride (WF₆) based selective process (tungsten over dielectric material of the sidewalls 924a, 924b of the cavity 910, etc.)), as shown in FIG. 9F. In some embodiments, a conformal gapfill may be used instead of a bottom-up fill. In some embodiments, for example, the cavity 910 may be filled by conformal CVD using tungsten or molybdenum and the like. In some embodiments, a conformal molybdenum fill can be performed by using MoO₂Cl₂ or MoOCl₄+H₂ processes or a mixture of MoCl₅ with the aforementioned two precursors.

As stated previously, in addition to tungsten as a TiSi capping layer, molybdenum (Mo) can be used as a capping material as well by selective Mo process. Similarly, the structure fill can be done by selective Mo fill or conformal Mo fill. In some embodiments, Mo and W materials can be interchanged or mixture of Mo and W used.

In FIG. 9F, a resultant conformal metal gap fill material 928 has been conformally deposited into cavity 910. In FIG. 9F, metal gap fill material 928 is shown filling the cavity 910. The metal gap fill material 928 is shown in contact with the metal cap 912 such that the metal gap fill material 928 is in electrical communication with the contact structure, e.g., silicon-based portion 904.

Any suitable deposition process, including but not limited to CVD or ALD processes, may be utilized for the metal gap fill material process. The metal gap fill material may be applied such that the material is deposited onto the bottom portion of the device feature and then grown upwards towards the semiconductor field region such that the resultant gap fill material at least approaches the field region, as shown in FIG. 9F) or is at least partially level with the field region (not shown).

In one or more embodiments, the metal gap fill material includes one or more of cobalt (Co), molybdenum (Mo), tungsten (W), tantalum (Ta), titanium (Ti), ruthenium (Ru), rhodium (Rh), copper (Cu), iron (Fe), manganese (Mn), vanadium (V), niobium (Nb), hafnium (Hf), zirconium (Zr), yttrium (Y), aluminum (AI), tin (Sn), chromium (Cr), lanthanum (La), iridium (Ir), or any combination thereof. In one or more embodiments, the metal gap fill material includes tungsten (e.g., deposited using WF₆). In one or more embodiments, the conductor material includes molybdenum.

### Gap Fill Process Examples

The methods of the present disclosure can be effective for metal gapfill processes in general and may be used with other metal gapfill material besides molybdenum such as, for example, tungsten and the like. For the sake of brevity, examples discussed herein include gapfill processes that include molybdenum which are not meant to be limit the scope of the disclosure provided herein and thus can include materials other than molybdenum.

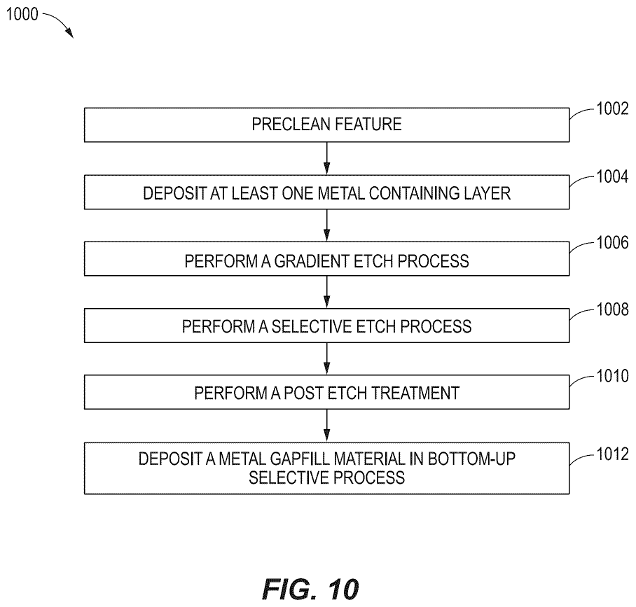

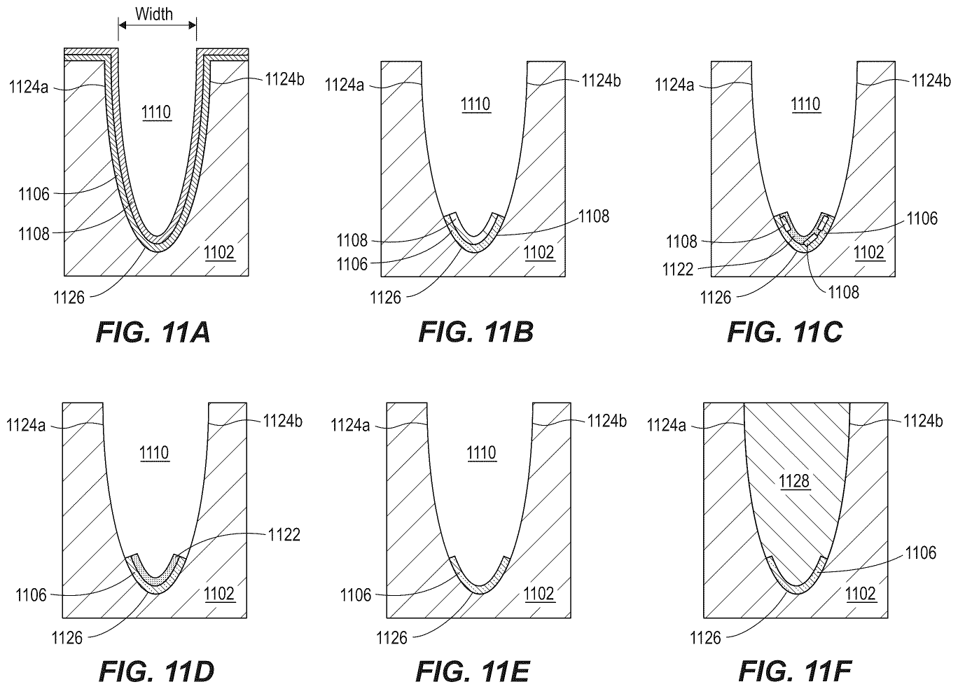

In the method 1000 of FIG. 10, an etch process is shown. In the discussion of the method 1000, references will be made to FIGS. 11A-11F. The method disclosed below may be applied to any of the above referenced methods (e.g., Method 200, Method 400, Method 600, and/or Method 800) that include an etch process or operation. At operation 1002, a preclean process is performed to remove any contaminates and/or oxidation from surfaces of a feature. The feature includes a cavity 1110 of a substrate 1102 formed of a dielectric material (e.g., silicon dioxide, silicon nitride, etc.). In some embodiments, the materials at the surface of the cavity 1110 may be a silicon material or a silicon germanium (SiGe) material.

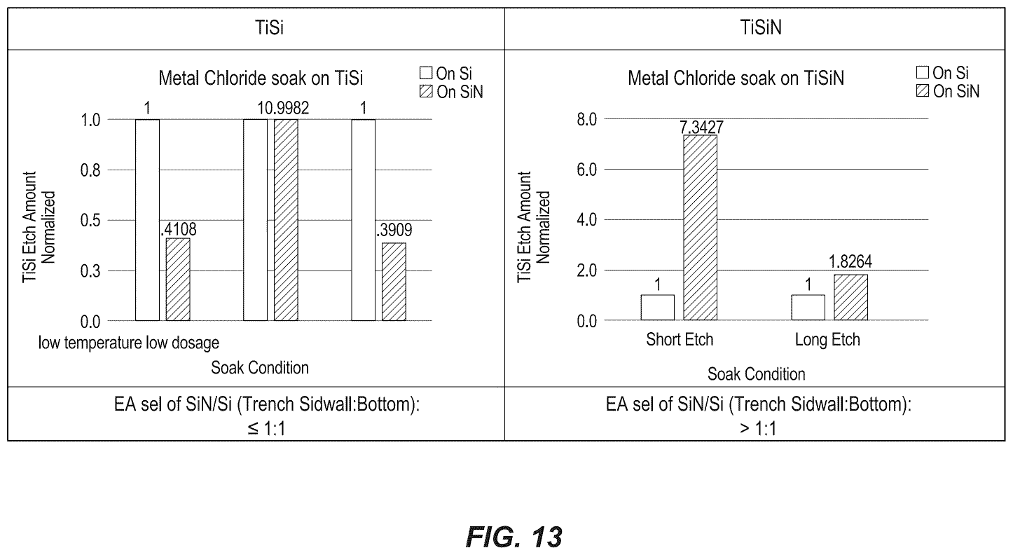

In one or more embodiments, cavities (e.g., vias, trenches, etc.) can have an average width. For example, the cavity 1110 can have a width (shown in FIG. 13A) of about 35 nanometers (nm) or less, such as about 5 nm to about 35 nm, such as about 5 nm, 10 nm, and 15 nm to about 20 nm, 25 nm, 30 nm, or 35 nm. In one or more embodiments, cavities (e.g., vias) can have an average critical dimension of about 1 nanometer (nm) to about 20 nm. For example, the cavity 1110 can have a critical dimension, e.g., a width between a first sidewall 1124a and a second sidewall 1124b of the features, of about 20 nanometers (nm) or less, such as about 1 nm to about 15 nm, such as about 1 nm, 5 nm, and 10 nm to about 12 nm, 15 nm, or 20 nm. Without being bound by theory, the present methods can allow for the deposition of a molybdenum gap fill material having no and/or reduced seams within the gap fill material. In one or more embodiments, cavity 1110 can have an aspect ratio (depth:width) of about 1:1 to about 100:1, such as about 10:1, 15:1, or 25:1 to about 35:1, 45:1, or 50:1.

At operation 1004, a deposition process is performed to produce at least one metal containing layer. For example, as shown in FIG. 11A, a first deposition process is performed to produce a first metal containing layer 1106 and a second deposition process is performed to produce a second metal containing layer 1108. Additionally or alternatively, the second metal containing layer 1108 is formed by a nitridation process or oxidation process performed on the first metal containing layer 1106. The deposition processes, the nitridation processes and/or the oxidation processes are described above in Method 200, Method 400, Method 600, and/or Method 800. Any of the deposition, nitridation, and/or oxidation processes may be applicable to produce at least one metal containing layer as shown in FIG. 11A. For example, as shown in FIG. 11A, the first metal containing layer 1106 can include a Ti layer and/or a TiSi layer. TiSi is TiₓSi_{y} which may include Ti₅Si₃, TiSi₂, TiSi, or combinations thereof. The second metal containing layer 1108 can include TiSiN and/or TiN. The formation process can provide a thickness of the first metal containing layer of approximately 3 nm to approximately 9 nm on the first sidewall 1124a, the second sidewall 1124b, and/or the bottom surface 1126. In some embodiments, the thickness of the first metal containing layer 1106 is conformal along the first sidewall 1124a, the second sidewall 1124b, and the bottom surface 1126. The formation process can provide a thickness of the second metal containing layer of approximately 3 nm to approximately 9 nm over the first metal containing layer 1106. The second metal containing layer 1108 is conformal along the first metal containing layer 1106. The deposition process can be performed using any suitable CVD or ALD process. In some embodiments, the CVD or ALD process includes utilizing a plasma with a carrier gas. The plasma/carrier gas may then be introduced towards the surface of the semiconductor substrate. In one or more embodiments, the carrier gas includes a noble gas, such as argon, neon, helium, or combinations thereof.

At operation 1006, a gradient etch process is performed to remove a portion of the first metal containing layer 1106 and the second metal containing layer 1108, as shown in FIG. 11B. The gradient etch process includes immersing the feature in a induction coupled plasma containing Cl₂ and other dilution gases, typically operated at about 5 mT to about 100 mT with a total gas flow of about 60 sccm to about 500 sccm. In one or more embodiments, the substrate 1102 is maintained at a temperature of between 0° C. and 50° C. In one or more embodiments, the feature is immersed in the above mentioned Cl₂ plasma for about 10 seconds to about 60 seconds, such as for about 50 seconds. The gradient etch process may continue for any amount of time until the first metal containing layer 1106 and the second metal containing layer 1108 are etched away to a desired height. In one or more embodiments, the gradient etch process is repeated in a cycle for R times. The cycle is repeated until the first metal containing layer 1106 and the second metal containing layer 1108 is etched away to a desired height. For example, as shown in FIG. 11B the first metal containing layer 1106 and the second metal containing layer 1108 is etched away from a portion of the first sidewall 1124a and the second sidewall 1124b such that a portion of the first metal containing layer 1106 and a portion of the second metal containing layer 1108 remains on the bottom surface 1126 of the cavity 1110.

At operation 1008, a selective etch process is performed to remove the second metal containing layer 1108. The selective etch process includes a selective deposition operation, an etch operation, and a trim operation. In one or more embodiments, the selective etch process is sequentially repeated in a cycle for R times until the second metal containing layer 1108 is etched away. For example, the selective etch process is sequentially repeated between 2 and 100 cycles. In one or more embodiments, the deposition operation and the etch operation occur simultaneously.

The deposition process is fulfilled in induction coupled plasma containing carbon-based precursors and dilution gas such as Ar. The process is operated at the similar regime as the gradient etching process. For example, the temperature is about 0° C. to 50° C., the pressure is about 5 mT to about 100 mT, and the flow regime is about 50 sccm to about 500 sccm. The one or more carbon-containing precursors can be used to provide the carbon at the surface of the first metal containing layer 1106 and the second metal containing layer 1108. The one or more carbon-containing precursors can include carbon precursors such as methane (CH₄), ethane (C₂H₆), acetylene (C₂H₂), ethylene (C₂H₄), propylene (C₃H₆), propane (C₃H₈), hexane (C₆H₁₄), benzene (C₆H₆), isoprene (C₅H₈), butadiene (C₄H₆), isomers thereof, or a combination thereof. The deposition operation results in a carbon-containing passivation layer 1122 disposed over at least a portion of the first metal containing layer 1106, and at least a portion of the second metal containing layer 1108. The carbon-containing passivation layer 1122 is selective to the first metal containing layer 1106. For example, a first metal containing layer 1106 comprising TiSi accumulates a carbon-containing passivation layer 1122 with a thickness greater than the carbon-containing passivation layer 1122 deposited over the second metal containing layer 1108 comprising TiN. The deposition process can be performed using any suitable CVD or ALD process with plasma capability. In one or more embodiments, the carrier gas includes a noble gas, such as argon, neon, helium, or combinations thereof.

The etch operation is similar to the gradient etching process, as described above, and is tailored such that the etching amount on layer 1106 is saturated after a few cycles while the etching of layer 1108 is sustaining as the cycles increases.

As shown in FIG. 11C, as the second metal containing layer 1108 is etched away, the first metal containing layer 1106 is exposed. The carbon-containing passivation layer 1122 is deposited over the exposed portion of the first metal containing layer 1106 and the second metal containing layer 1108. The carbon-containing passivation layer 1122 disposed over the first metal containing layer 1106 includes a thickness that is greater than the thickness of the carbon-containing passivation layer 1122 disposed over the second metal containing layer 1108.

The trim operation includes exposing the carbon-containing passivation layer 1122 with non-ionizing H₂ plasma. The plasma generated may have the etchants dissociated to form relatively mild and gentle etchants, so as gradually etch the carbon-containing passivation layer from the first metal containing layer 1106 and the second metal containing layer 1108. The H₂ plasma etches the carbon-containing passivation layer or “trims” the carbon-containing passivation layer 1122. The H₂ plasma removes at least most or all of the carbon-containing passivation layer 1122 from the second metal containing layer 1108 such that the second metal containing layer 1108 is exposed. In one or more embodiments, at least a portion of the carbon-containing passivation layer 1122 is etched away from the first metal containing layer 1106 such that at least a portion of the carbon-containing passivation layer 1122 remains on the first metal containing layer 1106. In one or more embodiments, at least a portion of the second metal containing layer 1108 and a portion of the carbon-containing passivation layer 1122 are etched away from the first metal containing layer 1106 such that a portion of the carbon-containing passivation layer remains on the first metal containing layer 1106.

The H₂ plasma is formed by supplying a hydrogen containing gas and an inert gas to a processing chamber. Suitable examples of the hydrogen containing gas include H₂, H₂O, H₂O₂, and the like. Suitable examples of the inert gas may also be supplied into the pre-cleaning gas mixture as needed. Examples of the inert gas supplied in the gas mixture include Ar, He, Ne, Kr, Xe and the like. In at least one embodiment, the pre-cleaning gas mixture includes H₂.

In at least one embodiment, H₂ is flowed into a processing chamber at a flow rate of about 200 sccm to about 2,000 sccm. A carrying gas may optionally be supplied into the processing chamber at a ratio of H₂ to carrier gas of about 5:95 to about 99.8:0.2. In at least one embodiment, He is used as the carrying gas and the He is supplied into the processing chamber at a H₂:He ratio of 5:95. The processing chamber is operated at a temperature of about 0° C. to about 50° C., a pressure of about 5 mT to about 500 mT, and a radio-frequency (RF) power of about 200 W to about 1,000 W for about 60 seconds to about 300 seconds.

When operation 1008 is repeated, the etch operation of the selective etch process is operable to etch both the second metal containing layer 1108 and the carbon-containing passivation layer 1122 simultaneously. Operation 1008 is repeated until the second metal containing layer 1108 is etched away. After Operation 1008, as shown in FIG. 11D, is completed the first metal containing layer 1106 and at least some of the carbon-containing passivation layer 1122 is disposed along the bottom surface 1126 of the cavity 1110.

At operation 1010, a post etch treatment process is performed. The post etch treatment includes exposing the carbon-containing passivation layer 1122 disposed over the first metal containing layer 1106 with non-ionizing H₂ plasma such that the carbon-containing passivation layer 1122 is etched away. As shown in FIG. 11E, the carbon-containing passivation layer 1122 is etched away and the first metal containing layer 1106 remains conformal to the bottom surface 1126 of the cavity 1110. The H₂ plasma is formed by supplying a hydrogen containing gas and an inert gas to a processing chamber. Suitable examples of the hydrogen containing gas include H₂, H₂O, H₂O₂, and the like. Suitable examples of the inert gas may also be supplied into the pre-cleaning gas mixture as needed. Examples of the inert gas supplied in the gas mixture include Ar, He, Ne, Kr, Xe and the like. In at least one embodiment, the pre-cleaning gas mixture includes H₂

In at least one embodiment, which can be combined with other embodiments, the at least one pretreatment process includes, flowing H₂ into a processing chamber at a flow rate of about 200 sccm to about 5,400 sccm. A carrying gas may optionally be supplied into the processing chamber at a ratio of H₂ to carrier gas of about 5:95 to about 99.8:0.2. In at least one embodiment, He is used as the carrying gas and the He is supplied into the processing chamber at a H₂:He ratio of 5:95. In at least one embodiment, water (H₂O) is used in place of the carrying gas and the H₂O is supplied into the processing chamber at a H₂:H₂O ratio of 99.6:0.4. The processing chamber is operated at a temperature of about 120° C. to about 350° C., a process pressure of about 50 mT to about 20 T, and a radio-frequency (RF) power of about 5200 W to about 36,000 W for about 60 seconds to about 300 seconds.

At operation 1012, as shown in FIG. 11F, a bottom-up metal gap fill material 1128 has been deposited into cavity 1110, thereby filling the cavity 1110. The metal gap fill material 1128 is shown in contact with the bottom portion of the first metal containing layer 1106 which is conformal to the bottom surface 1126 of the feature. The metal gap fill material 1128 is also in contact with at least a portion of the sidewalls 1124a, 1124b. In one or more embodiments, the metal gap fill material 1128 is deposited or filled according to any of the methods described above such as Method 200, Method 400, Method 600, and/or Method 800.

### Example Processing System

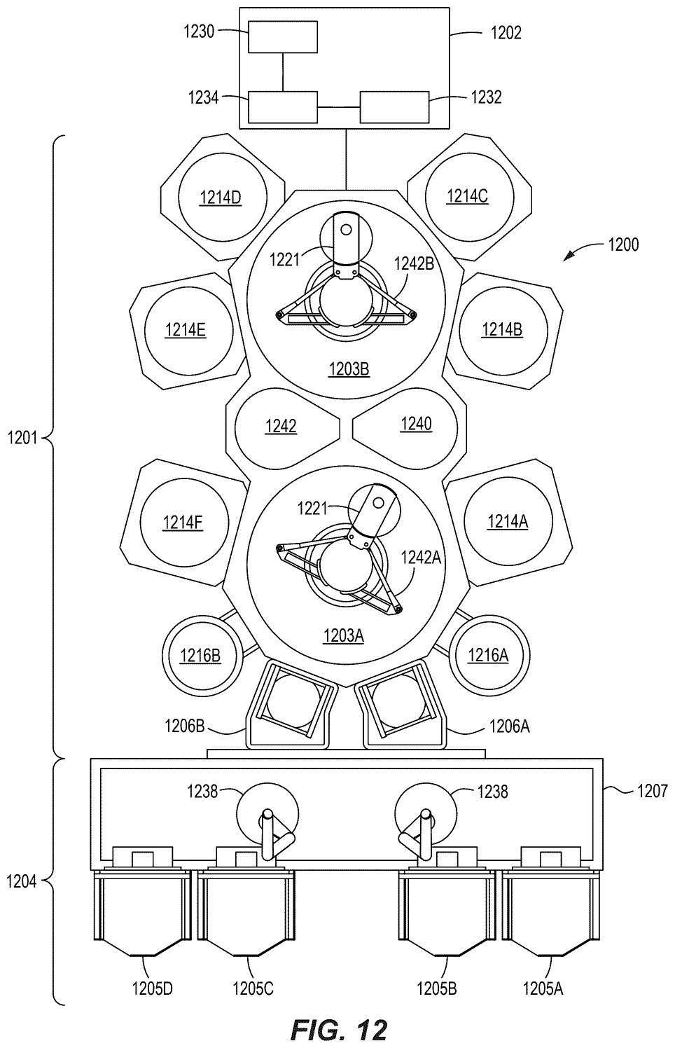

The methods of the present disclosure may be performed in individual process chambers that may be provided as part of a cluster tool, for example, the integrated tool 1200 (e.g., cluster tool) described below with respect to FIG. 12. The advantage of using an integrated tool 1200 is that there is no vacuum break between chambers and, therefore, no requirement to degas and pre-clean a substrate before treatment in a chamber. For example, in some embodiments the methods of the present disclosure may advantageously be performed in an integrated tool such that there are limited or no vacuum breaks between processes, limiting or preventing contamination of the substrate such as oxidation and the like. The integrated tool 1200 includes a vacuum-tight processing platform 1201, a factory interface 1204, and a system controller 1202. The vacuum-tight processing platform 1201 comprises multiple processing chambers, such as 1214A, 1213B, 1214C, 1214D, 1214E, and 1214F operatively coupled to a vacuum substrate transfer chamber (transfer chambers 1203A, 1203B). The factory interface 1204 is operatively coupled to the transfer chamber 1203A by one or more load lock chambers (two load lock chambers, such as 1206A and 1206B shown in FIG. 12).

In some embodiments, the factory interface 1204 comprises at least one docking station 1207, at least one factory interface robot 1238 to facilitate the transfer of the semiconductor substrates. The docking station 1207 is configured to accept one or more front opening unified pod (FOUP). Four FOUPS, such as 1205A, 1205B, 1205C, and 1205D are shown in the embodiment of FIG. 12. The factory interface robot 1238 is configured to transfer the substrates from the factory interface 1204 to the vacuum-tight processing platform 1201 through the load lock chambers, such as 1206A and 1206B. Each of the load lock chambers 1206A and 1206B have a first port coupled to the factory interface 1204 and a second port coupled to the transfer chamber 1203A. The load lock chamber 1206A and 1206B are coupled to a pressure control system (not shown) which pumps down and vents the load lock chambers 1206A and 1206B to facilitate passing the substrates between the vacuum environment of the transfer chamber 1203A and the substantially ambient (e.g., atmospheric) environment of the factory interface 1204. The transfer chambers 1203A, 1203B have vacuum robots 1242A, 1242B disposed in the respective transfer chambers 1203A, 1203B. The vacuum robot 1242A is capable of transferring substrates 1221 between the load lock chamber 1206A, 1206B, the processing chambers 1214A and 1214F and a cooldown station 1240 or a pre-clean station 1242. The vacuum robot 1242B is capable of transferring substrates 1221 between the cooldown station 1240 or pre-clean station 1242 and the processing chambers 1214B, 1214C, 1214D, and 1214E.

In some embodiments, the processing chambers 1214A, 1214B, 1214C, 1214D, 1214E, and 1214F are coupled to the transfer chambers 1203A, 1203B. The processing chambers 1214A, 1214B, 1214C, 1214D, 1214E, and 1214F may comprise, for example, preclean chambers, ALD process chambers, PVD process chambers, remote plasma chambers, CVD chambers, or the like. The chambers may include any chambers suitable to perform all or portions of the methods of the present disclosure, as discussed above, such as PVD W or PVD Mo chambers, CVD chambers, ALD chambers and the like. In some embodiments, one or more optional service chambers (shown as 1216A and 1216B) may be coupled to the transfer chamber 1203A. The service chambers 1216A and 1216B may be configured to perform other substrate processes, such as degassing, orientation, substrate metrology, cool down, and the like.

The processing chambers 1214A, 1214B, 1214C, 1214D, 1214E, and 1214F may be any appropriate chamber for processing a substrate. In some examples, a processing chamber may be capable of performing an etch process, a cleaning process, an annealing process, a CVD deposition process, or an ALD deposition process. As used herein, CVD refers to chemical vapor deposition and ALD refers to atomic line deposition. In some embodiments, a processing chamber is a Selectra™ Etch chamber available from Applied Materials of Santa Clara, Calif. In some embodiments, a processing chamber is a SiCoNi™ Pre-clean chamber available from Applied Materials of Santa Clara, Calif. In some embodiments, a processing chamber may be a Centura™ Epi chamber, Volta™ CVD/ALD chamber, or Encore™ PVID chamber, all available from Applied Materials of Santa Clara, Calif.

The system controller 1202 controls the operation of the tool 1200 using a direct control of the process chambers 1214A, 1214B, 1214C, 1214D, 1214E, and 1214F or alternatively, by controlling the computers (or controllers) associated with the process chambers 1214A, 1214B, 1214C, 1214D, 1214E, and 1214F and the tool 1200. In operation, the system controller 1202 enables data collection and feedback from the respective chambers and systems to optimize performance of the tool 1200. The system controller 1202 generally includes a Central Processing Unit (CPU) 1230, a memory 1234, and a support circuit 1232. The CPU 1230 may be any form of a general-purpose computer processor that can be used in an industrial setting. The support circuit 1232 is conventionally coupled to the CPU 1230 and may comprise a cache, clock circuits, input/output subsystems, power supplies, and the like. Software routines, such as a method as described above may be stored in the memory 1234 and, when executed by the CPU 1230, transform the CPU 1230 into a specific purpose computer (system controller). The software routines may also be stored and/or executed by a second controller (not shown) that is located remotely from the tool 1200.

### EXAMPLES

### Example 1

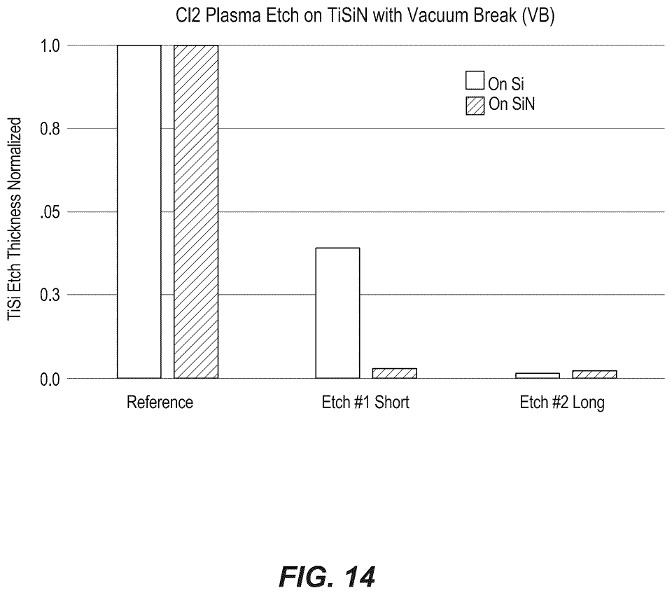

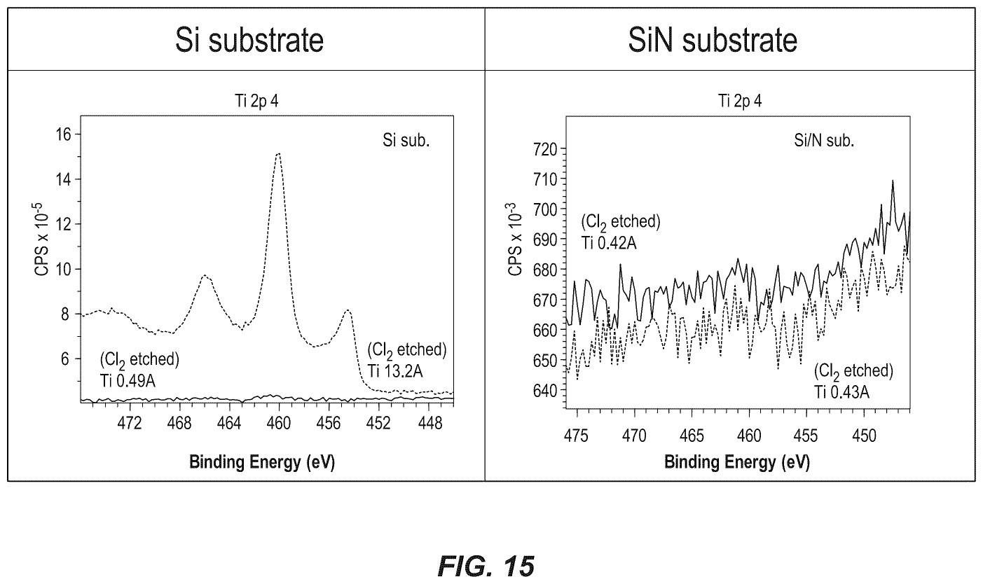

Etch amounts of TiSi when disposed on Si and SiN were performed when etching with MoCl₅ as an etchant gas, as shown in FIG. 15. The etching process was performed with a substrate temperature of 300° C. to 480° C. and an ampoule temperature of 60° C. to 100° C. TiSi resulted in higher etch amounts using metal chloride as an etchant gas when disposed on Si compared to SiN. TiSiN resulted in higher etch amounts using metal chloride as an etchant gas when disposed on SiN compared to Si. Moreover, an etchant gas of chlorine containing gas such as Cl₂, a carrier gas of inert gas in the presence of a plasma, was shown to etch both TiSiN and TiSi when deposited on both Si and SiN substrates, as shown in FIGS. 13 and 14. The temperature of the wafer was 0° C. to 60° C. and the pressure was 2-30 mT. A bias on the substrate was 50 Wb, and the plasma power was 200 W to 500 W. The dose time was 5 seconds to 30 seconds.

### Example 2

In an effort to selectively etch a metal containing layer to preferentially remove an upper region of the metal containing layer and leave a portion of the metal containing layer in a lower portion of a feature a “soak” type of etching process was performed. TiN when disposed on Si and SiN was etched with MoCl₅. The etching process was performed at a pressure of 10 Torr to about 20 Torr, and an ampoule temperature of about 95° C. Without being bound by theory, a pressure below 10 Torr resulted in higher etch rates, thereby damaging the bottom portion of the nitrided layer, whereas a pressure about 20 Torr resulted in lower etch rates, thereby preventing sufficient etching of the nitrided layer. The etching process included introducing an etchant gas of a chlorine containing gas such as MoCl₅, a carrier gas comprising an inert gas, and a processing gas, e.g., hydrogen. The etchant gas was introduced to the processing chamber at a flow rate of about 800 sccm to about 900 sccm. The carrier gas was introduced to the processing chamber at a flow rate of about 500 sccm to about 4000 sccm. A hydrogen bake process was performed on the feature at a pressure of about 10 Torr for about 90 seconds.

The gap fill process was performed at a pressure of 40 Torr to about 60 Torr, a pedestal temperature of about 450° C., and an ampoule temperature of about 95° C. The gap fill process included introducing a purge gas, e.g., argon, and a processing gas, e.g., hydrogen, for a period of 10 seconds. The purge gas was introduced to the processing chamber at a flow rate of about 5 slm to about 10 slm, and the processing gas was introduced to the processing chamber at a flow rate of about 10 slm to about 20 slm. Concurrently, the gap fill process included introducing an etchant gas, e.g., MoCl₅ for a period of about 4 seconds, followed by a rest period of about 6 seconds. The process was repeated for a number of cycles, e.g., about 80 cycles to about 100 cycles. The process allowed for the top portion of the nitrided layer to be etched such that less than 20% of the nitrided layer remained along the bottom surface of the cavity.

Embodiments in accordance with the present principles may be implemented in hardware, firmware, software, or any combination thereof. Embodiments may also be implemented as instructions stored using one or more computer readable media, which may be read and executed by one or more processors. A computer readable medium may include any mechanism for storing or transmitting information in a form readable by a machine (e.g., a computing platform or a “virtual machine” running on one or more computing platforms). For example, a computer readable medium may include any suitable form of volatile or non-volatile memory. In some embodiments, the computer readable media may include a non-transitory computer readable medium.

Certain embodiments and features have been described using a set of numerical upper limits and a set of numerical lower limits. It should be appreciated that ranges including the combination of any two values, e.g., the combination of any lower value with any upper value, the combination of any two lower values, and/or the combination of any two upper values are contemplated unless otherwise indicated. Certain lower limits, upper limits and ranges appear in one or more claims below. All numerical values are “about” or “approximately” the indicated value, and take into account experimental error and variations that would be expected by a person having ordinary skill in the art.

Likewise whenever a composition, an element or a group of elements is preceded with the transitional phrase “comprising”, it is understood that we also contemplate the same composition or group of elements may be modified with other transitional phrases, such as “consisting essentially of,” “consisting of”, “selected from the group of consisting of,” or “is” preceding the recitation of the composition, element, or elements and vice versa. The phrases, unless otherwise specified, “consists essentially of” and “consisting essentially of” do not exclude the presence of other steps, elements, or materials, whether or not, specifically mentioned in this specification, so long as such steps, elements, or materials, do not affect the basic and novel characteristics of the claimed features, additionally, the phrases do not exclude impurities and variances normally associated with the elements and materials used.

### Enumerated Embodiments

E1. A method of forming a contact structure on a semiconductor substrate, comprising: forming a metal silicide layer on a surface of the contact structure by maintaining a first temperature of a substrate and providing a first carrier gas, a first metal-containing precursor, and a first hydrogen-containing precursor to a first deposition chamber, wherein the contact structure comprises a feature formed in a surface of the semiconductor substrate, the feature comprises an opening that is defined by a silicon containing contact and sidewalls, which comprise a dielectric material, and the metal silicide layer is formed over the sidewalls and the silicon containing contact; exposing the metal silicide layer formed over the sidewalls and the silicon containing contact to a nitrogen containing plasma to cause a portion of the metal silicide layer to form a nitrided metal silicide layer; exposing the nitrided metal silicide layer to a chlorine (Cl₂) containing plasma to remove the portion of the nitrided metal silicide layer from the sidewalls and the silicon containing contact; and forming a metal layer on a surface of the silicon containing contact, wherein a portion of the formed metal silicide layer is disposed between the metal layer and the surface of the silicon containing contact.

E2. The method of embodiment E1, wherein: the first hydrogen-containing precursor is H₂, the first metal-containing precursor is TiCl₄, and the first temperature of the substrate is about 200° C. to 800° C.

E3. The method of embodiment E1, wherein the semiconductor substrate is exposed to an atmospheric environment between the exposing the metal silicide layer to the nitrogen containing plasma process and the exposing the nitrided metal silicide layer to the chlorine (Cl₂) containing plasma process.

E4. The method of embodiment E1, wherein the metal layer comprises tungsten, molybdenum, or combinations thereof.

E5. The method of embodiment E1, wherein the metal silicide layer comprises titanium silicide.

E6. The method of embodiment E5, wherein the nitrided metal silicide layer comprises titanium silicide nitride.

E7. A method of forming a contact structure on a semiconductor substrate, comprising: forming a metal silicide layer on a surface of the contact structure by maintaining a first temperature of a substrate and providing a first carrier gas, a first metal-containing precursor, and a first hydrogen-containing precursor to a first deposition chamber, wherein the contact structure comprises a feature formed in a surface of the semiconductor substrate, the feature comprises an opening that is defined by a silicon containing contact and sidewalls, which comprise a dielectric material, and the metal silicide layer is formed over the sidewalls and the silicon containing contact; exposing the metal silicide layer to a chlorine (Cl₂) containing plasma to remove at least a portion of the metal silicide layer formed on the sidewalls; and forming a metal layer on a surface of the silicon containing contact, wherein a portion of the formed metal silicide layer is disposed between the metal layer and the surface of the silicon containing contact.

E8. The method of embodiment E7, wherein: the first hydrogen-containing precursor is H₂, the first metal-containing precursor is TiCl₄, and the first temperature of the substrate is about 200° C. to 800° C.

E9. The method of embodiment E7, wherein the metal silicide layer comprises titanium silicide.

E10. The method of embodiment E7, wherein the metal layer comprises tungsten, molybdenum, titanium or combinations thereof.

E11. A method of forming a contact structure on a semiconductor substrate, comprising: forming a metal silicide layer on a surface of the contact structure by maintaining a first temperature of a substrate and providing a first carrier gas, a first metal-containing precursor, and a first hydrogen-containing precursor to a first deposition chamber, wherein the contact structure comprises a feature formed in a surface of the semiconductor substrate, the feature comprises an opening that is defined by a silicon containing contact and sidewalls, which comprise a dielectric material, and the metal silicide layer is formed over the sidewalls and the silicon containing contact; exposing the metal silicide layer to a metal chloride containing precursor to remove at least a portion of the metal silicide layer from the sidewalls; and forming a metal layer on a surface of the silicon containing contact, wherein a portion of the formed metal silicide layer is disposed between the metal layer and the surface of the silicon containing contact.

E12. The method of embodiment E11, wherein: the first hydrogen-containing precursor is H₂, the first metal-containing precursor is TiCl₄, and the first temperature of the substrate is about 200° C. to 800° C.

E13. The method of embodiment E11, wherein exposing the metal silicide layer to the metal chloride containing precursor comprises: delivering a metal chloride containing precursor that comprises MoCl₅ or WCl₅ to the feature; and heating the semiconductor substrate to a temperature of about 300° C. to 550° C.

E14. The method of embodiment E13, wherein the metal chloride containing precursor comprises MoCl₅.

E15. The method of embodiment E13, wherein the metal chloride containing precursor comprises WCl₅.

E16. A method of forming a contact structure on a semiconductor substrate, comprising: forming a metal silicide layer on a surface of the contact structure by maintaining a first temperature of a substrate and providing a first carrier gas, a first metal-containing precursor, and a first hydrogen-containing precursor to a first deposition chamber, wherein the contact structure comprises a feature formed in a surface of the semiconductor substrate, the feature comprises an opening that is defined by sidewalls, which comprise a dielectric material, and a silicon containing contact, and the metal silicide layer is formed over the sidewalls and the silicon containing contact; exposing the metal silicide layer formed over the sidewalls and the silicon containing contact to an oxygen containing plasma to cause a portion of the metal silicide layer to form an oxidized metal silicide layer; exposing the oxidized metal silicide layer to an oxide removal process, wherein the oxide removal process comprises: exposing the oxidized metal silicide layer to a metal chloride containing precursor to remove at least a portion of the metal silicide layer from the sidewalls, and then exposing the substrate to a plasma or thermal based fluorine etching process; and forming a metal layer on a surface of the silicon containing contact, wherein a portion of the formed metal silicide layer is disposed between the metal layer and the surface of the silicon containing contact.

E17. The method of embodiment E16, wherein: the first hydrogen-containing precursor is H₂, the first metal-containing precursor is TiCl₄, and the first temperature of the substrate is about 200° C. to 800° C.

E18. The method of embodiment E16, wherein exposing the oxidized metal silicide layer to the metal chloride containing precursor comprises: delivering a metal chloride containing precursor that comprises WCl₅ to the feature.

E19. The method of embodiment E16, wherein the semiconductor substrate is exposed to an atmospheric environment between forming the metal silicide layer on the surface of the contact structure and the exposing the metal silicide layer to the oxygen containing plasma process.

E20. The method of embodiment E16, wherein the exposing the substrate to the plasma or thermal based fluorine etching process comprises exposing the substrate to a gas mixture comprising NF₃, H₂, HF and NH₃.

E21. A method of forming a contact structure on a semiconductor substrate, comprising: forming a titanium layer on a surface of the contact structure by maintaining a first temperature of a substrate and providing a first carrier gas, a first metal-containing precursor, and a first hydrogen-containing precursor to a first deposition chamber, wherein the contact structure comprises a feature formed in a surface of the semiconductor substrate, the feature comprises an opening that is defined by a silicon containing contact, a bottom surface, and sidewalls, which comprise a dielectric material, and the titanium layer is at least formed over the sidewalls and the silicon containing contact; forming a first selective capping layer over the titanium layer by maintaining a second temperature of the substrate and providing a second carrier gas, a second metal-containing precursor, a first nitrogen-containing precursor, and a second hydrogen-containing precursor to the first deposition chamber; exposing the titanium layer and the first selective capping layer to an etchant gas containing plasma to remove at least a portion of the titanium layer and the first selective capping layer from the sidewalls; and forming a second selective capping layer over the silicon containing contact, wherein at least a portion of the formed titanium layer is disposed between the second selective capping layer and the surface of the silicon containing contact.

E22. The method of embodiment E21, wherein: the first hydrogen-containing precursor and the second hydrogen-containing precursor are H₂, the first metal-containing precursor and the second metal-containing precursor are TiCl₄, the first nitrogen-containing precursor is N₂, and the first temperature of the substrate is about 200° C. to 800° C.

E23. The method of embodiment E21, wherein the semiconductor substrate is exposed to an atmospheric environment between the forming the first selective capping layer process and forming the second selective capping layer.

E24. The method of embodiment E21, wherein the second selective capping layer comprises tungsten, molybdenum, or combinations thereof.

E25. The method of embodiment E21, wherein the titanium layer comprises titanium silicide.

E26. The method of embodiment E21, wherein the first selective capping layer comprises titanium nitride.

E27. The method of embodiment E21, wherein at least a portion of the first selective capping layer is disposed between the second selective capping layer and the titanium layer.

E28. The method of embodiment E21, wherein the first selective capping layer is disposed over the bottom surface of the feature.

E29. The method of embodiment E28, wherein the second selective capping layer is disposed over the first selective capping layer disposed over the bottom surface of the feature.

E30. The method of embodiment E21, further comprising: depositing a metal gap fill material over the first metal containing layer to fill the feature formed in the surface of the semiconductor substrate.

E31. The method of embodiment E21, wherein exposing the first selective capping layer and the second selective capping layer to the etchant gas containing plasma comprises: delivering a metal chloride containing precursor that comprises MoCl₅ or WCl₅ to the feature; and heating the semiconductor substrate to a temperature of about 300° C. to 550° C.

E32. A method of forming a contact structure on a semiconductor substrate, comprising: forming a titanium layer on a surface of the contact structure by maintaining a first temperature of a substrate and providing a first carrier gas, a first metal-containing precursor, and a first hydrogen-containing precursor to a first deposition chamber, wherein the contact structure comprises a feature formed in a surface of the semiconductor substrate, the feature comprises an opening that is defined by a silicon containing contact and sidewalls, which comprise a dielectric material, and the titanium layer is formed over the sidewalls and the silicon containing contact, and forming a conformal metal layer on a surface of the silicon containing contact, wherein a portion of the titanium layer is disposed between the conformal metal layer and the surface of the silicon containing contact.

E33. The method of embodiment E32, wherein: the first hydrogen-containing precursor is H₂, the first metal-containing precursor is TiCl₄, and the first temperature of the substrate is about 200° C. to 800° C.

E34. The method of embodiment E32, wherein the titanium layer comprises titanium silicide.

E35. The method of embodiment E32, wherein the conformal metal layer comprises tungsten, molybdenum, or combinations thereof.

E36. The method of embodiment E32 further comprising: forming a first selective capping layer over the titanium layer by maintaining a second temperature of a substrate and providing a second carrier gas, a second metal-containing precursor, a first nitrogen-containing precursor, and a second hydrogen-containing precursor to the first deposition chamber.

E37. The method of embodiment E36, wherein the first nitrogen-containing precursor is N₂.

E38. The method of embodiment E36, wherein the semiconductor substrate is exposed to an atmospheric environment (vacuum break) between the forming the second selective capping layer process and forming a conformal metal layer process.

E39. The method of embodiment E36, wherein the first selective capping layer comprises titanium nitride.

E40. The method of embodiment E36, wherein the conformal metal layer is formed over at least a portion of the first selective capping layer such that the titanium layer and the first selective capping layer is at least disposed between the silicon containing contact and the conformal metal layer.

E41. A method of forming a contact structure on a semiconductor substrate, comprising: providing a first metal containing layer and a second metal containing layer over a surface of the contact structure, wherein: the contact structure comprises a feature formed in a surface of the semiconductor substrate; the feature comprises an opening that is defined by a bottom surface and sidewalls, which comprise a dielectric material; the first metal containing layer is formed over the sidewalls and the bottom surface; and the second metal containing layer is formed over the first metal containing layer; performing a gradient etch process, the gradient etch process comprising: exposing the first metal containing layer and the second metal containing layer to an etchant gas containing plasma to remove at least a portion of the first metal containing layer and the second metal containing layer from the sidewalls; performing a selective etch process, the selective etch process comprising: a deposition operation, wherein the deposition operation comprises forming a carbon-containing passivation layer over the first metal containing layer and the second metal containing layer; an etch operation, wherein the etch operation comprises exposing the first metal containing layer, the second metal containing layer, and the carbon-containing passivation layer to an etchant gas; and a trim operation, wherein the trim operation comprises exposing at least the carbon-containing passivation layer and the second metal containing layer to a hydrogen plasma so that a portion of the carbon-containing passivation layer and a portion of the second metal containing layer is etched away; performing a post etch treatment process, the post etch treatment process comprising: exposing the first metal containing layer and the carbon-containing passivation layer with hydrogen plasma to remove at least a portion of the carbon-containing passivation layer; and depositing a metal gap fill material over the first metal containing layer to fill the feature formed in the surface of the semiconductor substrate.

E42. The method of embodiment E41, wherein the first metal containing layer comprises titanium silicide.

E43. The method of embodiment E41, wherein the second metal containing layer comprises titanium nitride.

E44. The method of embodiment E41, wherein the metal gap fill material comprises titanium, tungsten, molybdenum, or combinations thereof.

E45. The method of embodiment E41, wherein the gradient etch process comprises: delivering an induction coupled plasma comprising Cl₂ to the feature at a flow rate of about 60 sccm to about 500 sccm, a pressure of about 5 mT to about 100 mT, and a temperature of about 0° C. to about 50° C.

E46. The method of embodiment E41, wherein forming the carbon-containing passivation layer over the first metal containing layer and the second metal containing layer comprises: delivering a carbon-containing precursor that comprises methane (CH₄), ethane (C₂H₆), acetylene (C₂H₂), ethylene (C₂H₄), propylene (C₃H₆), propane (C₃H₈), hexane (C₆H₁₄), benzene (C₆H₆), isoprene (C₅H₈), butadiene (C₄H₆), isomers thereof, or a combination thereof to the feature; delivering the carbon-containing precursor to the feature at a pressure of about 5 mT to about 100 mT; and heating the semiconductor substrate to a temperature of about 300° C. to 550° C.

E47. The method of embodiment E41, wherein exposing the first metal containing layer, the second metal containing layer, and the carbon-containing passivation layer to an etchant gas comprises: delivering an induction coupled plasma comprising Cl₂ to the feature at a flow rate of about 60 sccm to about 500 sccm, a pressure of about 5 mT to about 100 mT, and a temperature of about 0° C. to about 50° C.

E48. The method of embodiment E41, wherein the selective etch process is sequentially repeated for 2 to 100 cycles.

E49. The method of embodiment E41, wherein exposing the first metal containing layer and the carbon-containing passivation layer with the hydrogen plasma to remove at least a portion of the carbon-containing passivation layer comprises: delivering a hydrogen containing precursor that comprises H₂, H₂O, H₂O₂, or a combination thereof to the feature; delivering an inert gas comprising Ar, He, Ne, Kr, or Xe to the feature; delivering the hydrogen containing precursor and the inert gas to the feature at a pressure of about 50 mT to about 20 T; and heating the semiconductor substrate to a temperature of about 120° C. to 350° C.

E50. The method of embodiment E41, wherein depositing the metal gap fill material comprises depositing the metal gap fill material using a chemical vapor deposition process.

E51. A method of forming a contact structure on a semiconductor substrate, comprising: forming a first metal containing layer on a surface of the contact structure by maintaining a first temperature of a substrate and providing a first carrier gas, a first metal-containing precursor, and a first hydrogen-containing precursor to a deposition chamber, wherein: the contact structure comprises a feature formed in a surface of the semiconductor substrate, the feature comprises an opening that is defined by a bottom surface and sidewalls, which comprise a dielectric material, and the first metal containing layer is formed over the sidewalls and the bottom surface; forming a second metal containing layer on the surface of the contact structure by maintaining a second temperature of the substrate and providing a second carrier gas, a second metal-containing precursor, a first nitrogen-containing precursor and a second hydrogen-containing precursor to the deposition chamber, wherein the second metal containing layer is formed over the first metal containing layer; performing a gradient etch process, the gradient etch process comprising: exposing the first metal containing layer and the second metal containing layer to an etchant gas containing plasma to remove at least a portion of the first metal containing layer and the second metal containing layer from the sidewalls; performing a selective etch process, the selective etch process comprising: a deposition operation; an etch operation; and a trim operation; performing a post etch treatment process, the post etch treatment process comprising: exposing the first metal containing layer and a carbon-containing passivation layer with a hydrogen plasma to remove at least a portion of the carbon-containing passivation layer; and depositing a metal gap fill material over the first metal containing layer to fill the feature formed in the surface of the semiconductor substrate.

E52. The method of embodiment E51, wherein: the first hydrogen-containing precursor and the second hydrogen-containing precursor are H₂, the first metal-containing precursor and the second metal-containing precursor are TiCl₄, the first nitrogen-containing precursor is N₂, and the first temperature of the substrate is about 200° C. to 800° C.

E53. The method of embodiment E51, wherein the first metal containing layer comprises titanium silicide.

E54. The method of embodiment E51, wherein the second metal containing layer comprises titanium nitride.

E55. The method of embodiment E51, wherein the gradient etch process comprises: delivering an induction coupled plasma comprising Cl₂ to the feature at a flow rate of about 60 sccm to about 500 sccm, a pressure of about 5 mT to about 100 mT, and a temperature of about 0° C. to about 50° C.

E56. The method of embodiment E51, wherein the deposition operation comprises forming the carbon-containing passivation layer over the first metal containing layer and the second metal containing layer.

E57. The method of embodiment E51, wherein the etch operation comprises exposing the first metal containing layer, the second metal containing layer, and the carbon-containing passivation layer to an etchant gas.

E58. The method of embodiment E51, wherein the trim operation comprises exposing at least the carbon-containing passivation layer and the second metal containing layer to H₂ plasma so that a portion of the carbon-containing passivation layer and a portion of the second metal containing layer is etched away.

E59. The method of embodiment E51, wherein the selective etch process is sequentially repeated for 2 to 100 cycles.

E60. The method of embodiment E51, wherein exposing the first metal containing layer and the carbon-containing passivation layer with the hydrogen plasma to remove at least a portion of the carbon-containing passivation layer comprises: delivering a hydrogen containing precursor that comprises H₂, H₂O, H₂O₂, or a combination thereof to the feature; delivering an inert gas comprising Ar, He, Ne, Kr, or Xe to the feature; delivering the hydrogen containing precursor and the inert gas to the feature at a pressure of about 50 mT to about 20; and heating the semiconductor substrate to a temperature of about 120° C. to 350° C.

Overall, methods of the present disclosure can integrate multiple deposition and etching processes on the same integrated tool to achieve low contact resistance (Rc). Methods of the present disclosure provide middle-end-of-the-line (MEOL) contacts with reduced resistivity. Methods can integrate multiple MEOL processes on the same integrated tool as well as achieve low contact resistance (Rc). Methods can provide selective etching of a capping layer by use of a selective etching process such that the selectivity towards the capping layer is maintained, thereby reducing resistivity by removing the capping layer prior to deposition of a W cap and/or liner. As a further example, a process has been developed that selectively etches a titanium silicon nitride layer by use of a selective etching process such that the deposition of a low resistance gap fill material is selective towards a bottom surface of the cavity, via, and/or trench, thereby reducing resistivity by preventing seam formation within the gap fill material.

While the foregoing is directed to embodiments of the present principles, other and further embodiments of the principles may be devised without departing from the basic scope thereof.

What is claimed is:

1. A method of forming a contact structure on a semiconductor substrate, comprising:
forming a metal silicide layer on a surface of the contact structure by maintaining a first temperature of a substrate and providing a first carrier gas, a first metal-containing precursor, and a first hydrogen-containing precursor to a first deposition chamber, wherein
the contact structure comprises a feature formed in a surface of the semiconductor substrate,
the feature comprises an opening that is defined by a silicon containing contact and sidewalls, which comprise a dielectric material, and
the metal silicide layer is formed over the sidewalls and the silicon containing contact;
exposing the metal silicide layer formed over the sidewalls and the silicon containing contact to a nitrogen containing plasma to cause a portion of the metal silicide layer to form a nitrided metal silicide layer;
exposing the nitrided metal silicide layer to a chlorine (Cl₂) containing plasma to remove the portion of the nitrided metal silicide layer from the sidewalls and the silicon containing contact; and
forming a metal layer on a surface of the silicon containing contact, wherein a portion of the formed metal silicide layer is disposed between the metal layer and the surface of the silicon containing contact.

2. The method of claim 1, wherein:
the first hydrogen-containing precursor is H₂,
the first metal-containing precursor is TiCl₄, and
the first temperature of the substrate is about 200° C. to 800° C.

3. The method of claim 1, wherein the semiconductor substrate is exposed to an atmospheric environment between the exposing the metal silicide layer to the nitrogen containing plasma process and the exposing the nitrided metal silicide layer to the chlorine (Cl₂) containing plasma process.

4. The method of claim 1, wherein the metal layer comprises tungsten, molybdenum, or combinations thereof.

5. The method of claim 1, wherein the metal silicide layer comprises titanium silicide.

6. The method of claim 5, wherein the nitrided metal silicide layer comprises titanium silicide nitride.

7. A method of forming a contact structure on a semiconductor substrate, comprising:
forming a metal silicide layer on a surface of the contact structure by maintaining a first temperature of a substrate and providing a first carrier gas, a first metal-containing precursor, and a first hydrogen-containing precursor to a first deposition chamber, wherein
the contact structure comprises a feature formed in a surface of the semiconductor substrate,
the feature comprises an opening that is defined by a silicon containing contact and sidewalls, which comprise a dielectric material, and
the metal silicide layer is formed over the sidewalls and the silicon containing contact;
exposing the metal silicide layer to a chlorine (Cl₂) containing plasma to remove at least a portion of the metal silicide layer formed on the sidewalls; and
forming a metal layer on a surface of the silicon containing contact, wherein a portion of the formed metal silicide layer is disposed between the metal layer and the surface of the silicon containing contact.

8. The method of claim 7, wherein:
the first hydrogen-containing precursor is H₂,
the first metal-containing precursor is TiCl₄, and
the first temperature of the substrate is about 200° C. to 800° C.

9. The method of claim 7, wherein the metal silicide layer comprises titanium silicide.

10. The method of claim 7, wherein the metal layer comprises tungsten, molybdenum, titanium or combinations thereof.

11. A method of forming a contact structure on a semiconductor substrate, comprising:
forming a metal silicide layer on a surface of the contact structure by maintaining a first temperature of a substrate and providing a first carrier gas, a first metal-containing precursor, and a first hydrogen-containing precursor to a first deposition chamber, wherein
the contact structure comprises a feature formed in a surface of the semiconductor substrate,
the feature comprises an opening that is defined by a silicon containing contact and sidewalls, which comprise a dielectric material, and
the metal silicide layer is formed over the sidewalls and the silicon containing contact;
exposing the metal silicide layer to a metal chloride containing precursor to remove at least a portion of the metal silicide layer from the sidewalls; and
forming a metal layer on a surface of the silicon containing contact, wherein a portion of the formed metal silicide layer is disposed between the metal layer and the surface of the silicon containing contact.

12. The method of claim 11, wherein:
the first hydrogen-containing precursor is H₂,
the first metal-containing precursor is TiCl₄, and
the first temperature of the substrate is about 200° C. to 800° C.

13. The method of claim 11, wherein exposing the metal silicide layer to the metal chloride containing precursor comprises:
delivering a metal chloride containing precursor that comprises MoCl₅ or WCl₅ to the feature;
and heating the semiconductor substrate to a temperature of about 300° C. to 550° C.

14. The method of claim 13, wherein the metal chloride containing precursor comprises MoCl₅.

15. The method of claim 13, wherein the metal chloride containing precursor comprises WCl₅.

16. A method of forming a contact structure on a semiconductor substrate, comprising:
forming a metal silicide layer on a surface of the contact structure by maintaining a first temperature of a substrate and providing a first carrier gas, a first metal-containing precursor, and a first hydrogen-containing precursor to a first deposition chamber, wherein
the contact structure comprises a feature formed in a surface of the semiconductor substrate,
the feature comprises an opening that is defined by sidewalls, which comprise a dielectric material, and a silicon containing contact, and
the metal silicide layer is formed over the sidewalls and the silicon containing contact;
exposing the metal silicide layer formed over the sidewalls and the silicon containing contact to an oxygen containing plasma to cause a portion of the metal silicide layer to form an oxidized metal silicide layer;
exposing the oxidized metal silicide layer to an oxide removal process, wherein the oxide removal process comprises:
exposing the oxidized metal silicide layer to a metal chloride containing precursor to remove at least a portion of the metal silicide layer from the sidewalls, and then
exposing the substrate to a plasma or thermal based fluorine etching process; and
forming a metal layer on a surface of the silicon containing contact, wherein a portion of the formed metal silicide layer is disposed between the metal layer and the surface of the silicon containing contact.

17. The method of claim 16, wherein:
the first hydrogen-containing precursor is H₂,
the first metal-containing precursor is TiCl₄, and
the first temperature of the substrate is about 200° C. to 800° C.

18. The method of claim 16, wherein exposing the oxidized metal silicide layer to the metal chloride containing precursor comprises:
delivering a metal chloride containing precursor that comprises WCl₅ to the feature.

19. The method of claim 16, wherein the semiconductor substrate is exposed to an atmospheric environment between forming the metal silicide layer on the surface of the contact structure and the exposing the metal silicide layer to the oxygen containing plasma process.

20. The method of claim 16, wherein the exposing the substrate to the plasma or thermal based fluorine etching process comprises exposing the substrate to a gas mixture comprising NF₃, H₂, HF and NH₃.
